(19) United States
(12) Patent Application Publication
(10) Pub. No.: US 2026/0244065 A1
(43) Pub. Date: Aug. 20, 2026

(54) ARRAY SUBSTRATE, ELECTRONIC PAPER DISPLAY DEVICE AND DRIVING METHOD THEREOF

(71) Applicants: BOE TECHNOLOGY GROUP CO., LTD., Beijing (CN); BEIJING BOE TECHNOLOGY DEVELOPMENT CO., LTD., Beijing (CN)

(72) Inventors: Xiaorong CUI, Beijing (CN); Baoxi WANG, Beijing (CN); Yuzhen GUO, Beijing (CN); Haoliang ZHENG, Beijing (CN); Li XIAO, Beijing (CN); Chenyang ZHANG, Beijing (CN); Jiao ZHAO, Beijing (CN); Minghua XUAN, Beijing (CN); Lipeng GAO, Beijing (CN); Yichi ZHANG, Beijing (CN)

(21) Appl. No.: 18/992,600

(22) PCT Filed: Aug. 24, 2023
(86) PCT No.: PCT/CN2023/114772

§ 371 Date: Jan. 9, 2025

(51) Int. Cl. G02F 1/1685; G02F 1/1362; G02F 1/1368; H10D 86/40

(52) U.S. Cl. CPC G02F 1/1685; G02F 1/136213; G02F 1/1368; H10D 86/441; H10D 86/451

(57) ABSTRACT

An array substrate, an electronic paper display device and a driving method thereof, the array substrate has pixel regions and includes: a base substrate, pixel electrodes and a barrier wall electrode structure; the pixel electrodes are respectively located in the pixel regions, and the barrier wall electrode structure is located between adjacent pixel regions, the pixel regions includes first and second pixel regions arranged in a first direction; the barrier wall electrode structure includes first, second and third barrier wall electrodes, at least portions of which are sequentially arranged between the first and second pixel regions in the first direction; the first and second barrier wall electrodes are configured to form a first electric field, the second and third barrier wall electrodes are configured to form a second electric field, the first and second electric fields are in opposite directions and configured to together constitute an electronic barrier wall.

### TECHNICAL FIELD

Embodiments of the present disclosure relate to an array substrate, an electronic paper display device and a driving method thereof.

### BACKGROUND

Compared with mainstream display technologies such as liquid crystal display and OLED display, the existing electronic paper display technology has the advantages of low power consumption and strong eye protection, and hence is widely used. The display principle of electronic paper display technology is to provide a vertical electric field between the electrodes in the upper and lower substrates which are disposed facing each other, and there are charged dispersed particles (for example, black particles and/or white particles) in the dispersant between the upper and lower substrates, and the aggregation form of the charged particles is controlled by controlling the vertical electric field, thereby controlling the display of the display device. However, in the existing electronic paper display device, charged particles in the dispersant may cause cross talk between adjacent pixel regions, which will adversely affect the display of the display device.

### SUMMARY

At least one embodiment of the present disclosure provides an array substrate, having a plurality of pixel regions arranged in an array and including: a base substrate; and a plurality of pixel electrodes and a barrier wall electrode structure, disposed on a side of the base substrate, wherein the plurality of pixel electrodes are respectively located in the plurality of pixel regions, and the barrier wall electrode structure is located between adjacent pixel regions, wherein the plurality of pixel regions includes a first pixel region and a second pixel region which are arranged in a first direction parallel to a main surface of the base substrate and are adjacent to each other, and the plurality of pixel electrodes include a first pixel electrode and a second pixel electrode respectively located in the first pixel region and the second pixel region; and the barrier wall electrode structure includes a first barrier wall electrode, a second barrier wall electrode and a third barrier wall electrode; at least a portion of the first barrier wall electrode, at least a portion of the second barrier wall electrode and at least a portion of the third barrier wall electrode are sequentially arranged between the first pixel region and the second pixel region in the first direction; the first barrier wall electrode and the second barrier wall electrode are configured to form a first electric field, the second barrier wall electrode and the third barrier wall electrode are configured to form a second electric field, the first electric field and the second electric field are in opposite directions and are configured to together constitute an electronic barrier wall; wherein the second barrier wall electrode is an electrode shared by the first electric field and the second electric field.

In the array substrate provided by at least one embodiment of the present disclosure, at least a part of the first barrier wall electrode is located at a periphery of the first pixel region and surrounds the first pixel region in a direction parallel to the main surface of the base substrate; and at least a part of the third barrier wall electrode is located at a periphery of the second pixel region and surrounds the second pixel region in the direction parallel to the main surface of the base substrate.

In the array substrate provided by at least one embodiment of the present disclosure, the second barrier wall electrode surrounds the first barrier wall electrode and surrounds the third barrier wall electrode in the direction parallel to the main surface of the base substrate.

In the array substrate provided by at least one embodiment of the present disclosure, the at least the portion of the second barrier wall electrode is located between the first barrier wall electrode and the third barrier wall electrode in the first direction, and has an opening, and the first barrier wall electrode and the third barrier wall electrode are electrically connected to each other through a connection electrode passing through the opening.

In the array substrate provided by at least one embodiment of the present disclosure, the plurality of pixel electrodes and the barrier wall electrode structure are disposed at a same layer and are spaced apart from each other.

In the array substrate provided by at least one embodiment of the present disclosure, the barrier wall electrode structure is disposed on a side of the plurality of pixel electrodes close to the base substrate, and an orthographic projection of the first barrier wall electrode on the base substrate covers the first pixel region and extends beyond an edge of an orthographic projection of the first pixel region on the base substrate; or an orthographic projection of the third barrier wall electrode on the base substrate covers the second pixel region and extends beyond an edge of an orthographic projection of the second pixel region on the base substrate.

In the array substrate provided by at least one embodiment of the present disclosure, each pixel electrode includes a plurality of pixel sub-electrodes, the plurality of pixel sub-electrodes are spaced apart from each other and configured to be connected to a plurality of data signal lines, respectively.

In the array substrate provided by at least one embodiment of the present disclosure, each of one or more of the plurality of data signal lines includes a data signal main line and a data signal auxiliary line connected to each other through a transfer electrode, and a plurality of data signal main lines is located in a region outside a corresponding pixel region.

In the array substrate provided by at least one embodiment of the present disclosure, orthographic projections of the plurality of data signal main lines on the base substrate are offset from a gap between orthographic projections of a plurality of pixel sub-electrodes located in a same pixel region on the base substrate.

In the array substrate provided by at least one embodiment of the present disclosure, the plurality of pixel sub-electrodes include a plurality of strip electrodes arranged along the first direction and extending along a second direction, and the first direction and the second direction intersect with each other.

In the array substrate provided by at least one embodiment of the present disclosure, the plurality of pixel sub-electrodes include a first pixel sub-electrode and a second pixel sub-electrode, and the second pixel sub-electrode surrounds the first pixel sub-electrode in a direction parallel to the main surface of the base substrate.

In the array substrate provided by at least one embodiment of the present disclosure, the barrier wall electrode structure is further multi-used as a reflective electrode.

The array substrate provided by at least one embodiment of the present disclosure further includes a plurality of transistors and a plurality of capacitors, wherein each transistor includes a gate electrode, a source electrode and a drain electrode, and each capacitor includes at least a first electrode plate and a second electrode plate, and a pixel sub-electrode of each pixel electrode is electrically connected with one of the source electrode and the drain electrode of a corresponding transistor and is electrically connected with one of the first electrode plate and the second electrode plate of a corresponding capacitor, and the array substrate includes: a first conductive layer, a first insulating layer, a second conductive layer and a second insulating layer, which are sequentially disposed on a side of the base substrate, wherein the gate electrode and the first electrode plate are located at the first conductive layer, and the source electrode, the drain electrode and the second electrode plate are located at the second conductive layer; and a first electrode layer, located on a side of the second insulating layer away from the base substrate, wherein the plurality of pixel electrodes are disposed at the first electrode layer, the second insulating layer is provided with a first via hole, and the pixel sub-electrode is connected to the source electrode or the drain electrode of the corresponding transistor through the first via hole.

In the array substrate provided by at least one embodiment of the present disclosure, the second conductive layer is provided with an opening; the second insulating layer and the first insulating layer are provided with a second via hole, and the second via hole passes through the opening of the second conductive layer and is spaced apart from the second conductive layer; and the pixel sub-electrode is electrically connected to the first electrode plate of a capacitor through the second via hole.

In the array substrate provided by at least one embodiment of the present disclosure, the capacitor further includes a third electrode plate, and the pixel sub-electrode is multi-used as the third electrode plate of the capacitor, and the capacitor includes double-layer capacitance formed between the second electrode plate and the first electrode plate, and between the second electrode plate and the third electrode plate.

In the array substrate provided by at least one embodiment of the present disclosure, the second electrode plate is configured to receive a common voltage signal and is multi-used as a signal shielding structure.

In the array substrate provided by at least one embodiment of the present disclosure, the barrier wall electrode structure is located at the first electrode layer, and the second insulating layer further includes a third via hole, and the first barrier wall electrode and the third barrier wall electrode are respectively connected to the second electrode plates of corresponding capacitors through the third via hole.

The array substrate provided by at least one embodiment of the present disclosure further includes: a second electrode layer, located on a side of the first electrode layer close to the base substrate, and located between the first electrode layer and the second insulating layer; and an organic layer, located between the first electrode layer and the second electrode layer, wherein the barrier wall electrode structure is located at the second electrode layer and is multi-used as a reflective electrode.

In the array substrate provided by at least one embodiment of the present disclosure, the first via hole extends from the organic layer into the second insulating layer, and the second electrode layer is provided with an opening, and the first via hole passes through the opening and is spaced apart from the second electrode layer, so that the pixel sub-electrode passes through the opening to be connected to the source electrode or the drain electrode of a corresponding transistor.

In the array substrate provided by at least one embodiment of the present disclosure, orthographic projections of the first barrier wall electrode and the third barrier wall electrode on the base substrate overlap with orthographic projections of the first pixel electrode and the second pixel electrode on the base substrate, respectively, and the first barrier wall electrode and the third barrier wall electrode are each provided with the opening.

In the array substrate provided by at least one embodiment of the present disclosure, the first insulating layer and the second insulating layer are provided with a third via hole, and the second conductive layer is provided with an opening, and the third via hole passes through the opening and is spaced apart from the second conductive layer; and the first barrier wall electrode and the third barrier wall electrode are electrically connected to the first electrode plates of the corresponding capacitors through the third via hole, respectively.

In the array substrate provided by at least one embodiment of the present disclosure, the first barrier wall electrode and the third barrier wall electrode are also served as third electrode plates of corresponding capacitors, and each capacitor includes double-layer capacitance formed between the second electrode plate and the first electrode plate and between the second electrode plate and the third electrode plate.

In the array substrate provided by at least one embodiment of the present disclosure, an orthographic projection of the first electrode layer on the base substrate overlaps with an orthographic projection of the second electrode layer on the base substrate, and the orthographic projection of the second electrode layer also covers an orthographic projection of a gap region between a plurality of pixel sub-electrodes in each pixel region on the base substrate.

In the array substrate provided by at least one embodiment of the present disclosure, each pixel electrode includes a first pixel sub-electrode, a second pixel sub-electrode and a third pixel sub-electrode which are arranged along the first direction; in each pixel region, a plurality of transistors includes a first transistor, a second transistor and a third transistor, which are respectively connected with the first pixel sub-electrode, the second pixel sub-electrode and the third pixel sub-electrode, respectively; wherein the first transistor and the second transistor are arranged along the first direction, the third transistor is located on a side of the first transistor and the third transistor in a second direction, and at least a portion of an orthographic projection of the third transistor on a reference plane extending along the first direction is located between orthographic projections of the first transistor and the second transistor on the reference plane, and the first direction intersects with the second direction.

In the array substrate provided by at least one embodiment of the present disclosure, the plurality of pixel regions are arranged in a plurality of pixel rows along the first direction and arranged in a plurality of pixel columns along the second direction; in a first pixel region and a third pixel region that are located in a same pixel column and in adjacent pixel rows, a plurality of transistors in the first pixel region are symmetrically disposed with a plurality of transistors in the third pixel region.

In the array substrate provided by at least one embodiment of the present disclosure, a first distance is provided between the first transistor in the first pixel region and the first transistor in the third pixel region; a second distance is provided between the second transistor in the first pixel region and the second transistor in the third pixel region; a third distance is provided between the third transistor in the first pixel region and the third transistor in the third pixel region; the first distance, the second distance and the third distance are all distances in the second direction; the first distance is as same as the second distance, and the third distance is different from the first distance and the second distance.

At least one embodiment of the present disclosure provides an electronic paper display device, including any one of the above-mentioned array substrates.

In the electronic paper display device provided by at least one embodiment of the present disclosure, the array substrate serves as a first substrate, and the electronic paper display device further includes: a second substrate, provided with a common electrode and disposed to face the first substrate; and a dispersant layer, located between the first substrate and the second substrate, and including charged particles located in the plurality of pixel regions.

In the electronic paper display device provided by at least one embodiment of the present disclosure, the charged particles include at least one of a first charged particle and a second charged particle, wherein the first charged particle has a first electrical property and the second charged particle has a second electrical property, and the first electrical property is opposite to the second electrical property.

In the electronic paper display device provided by at least one embodiment of the present disclosure, there is free of physical barrier wall provided between adjacent pixel regions.

The electronic paper display device provided by at least one embodiment of the present disclosure further includes a physical barrier wall disposed between the first substrate and the second substrate in a direction perpendicular to the main surface of the base substrate, and between adjacent pixel regions in a direction parallel to the main surface of the base substrate.

In the electronic paper display device provided by at least one embodiment of the present disclosure, the physical barrier wall overlaps with one or more barrier wall electrodes in the barrier wall electrode structure in the direction perpendicular to the main surface of the base substrate.

At least one embodiment of the present disclosure provides a driving method of an electronic paper display device, including: applying a first voltage, a second voltage and a third voltage to the first barrier wall electrode, the second barrier wall electrode and the third barrier wall electrode, respectively, wherein the first voltage is smaller than the second voltage, and the third voltage is smaller than the second voltage, so that an electronic barrier wall is formed by the barrier wall electrode structure and between the first pixel region and the second pixel region that are adjacent to each other and includes two electric fields which have opposite directions and face away from each other; or the first voltage is greater than the second voltage, and the third voltage is greater than the second voltage, so that an electronic barrier wall is formed by the barrier wall electrode structure and between the first pixel region and the second pixel region that are adjacent to each other and includes two electric fields which have opposite directions and face towards each other.

In the driving method of the electronic paper display device provided by at least one embodiment of the present disclosure, the first voltage is qual to the third voltage.

At least one embodiment of the present disclosure provides an array substrate, including a plurality of pixel regions arranged in an array, wherein the plurality of pixel regions are arranged in a plurality of pixel rows along a first direction and arranged in a plurality of pixel columns along a second direction, the first direction intersects with the second direction, and the array substrate includes: a base substrate; and a plurality of pixel electrodes and a barrier wall electrode structure, disposed on a side of the base substrate, wherein the plurality of pixel electrodes are located in the plurality of pixel regions respectively, and the barrier wall electrode structure is located between adjacent pixel regions; wherein the barrier wall electrode structure includes a plurality of first barrier wall electrodes and a second barrier wall electrode, the plurality of first barrier wall electrodes are disposed in one-to-one correspondence with the plurality of pixel regions, at least a portion of each first barrier wall electrode surrounds one corresponding pixel region in a direction parallel to a main surface of the base substrate, and each first barrier wall electrode is surrounded by the second barrier wall electrode in the direction parallel to the main surface of the base substrate.

In the array substrate provided by at least one embodiment of the present disclosure, the plurality of first barrier wall electrodes are configured to receive a first voltage signal, and the second barrier wall electrode is configured to receive a second voltage signal, which is different from the first voltage signal.

In the array substrate provided by at least one embodiment of the present disclosure, the plurality of first barrier wall electrodes are arranged in a plurality of rows along the first direction; a portion of the second barrier wall electrode between every two adjacent first barrier wall electrodes located in a same row is provided with an opening; the barrier wall electrode structure further includes a connection electrode, and the connection electrode passes through the opening, so that a plurality of first barrier wall electrodes located in a same row are electrically connected with each other through the connection electrode.

In the array substrate provided by at least one embodiment of the present disclosure, the second barrier wall electrode is in a grid shape and defines a plurality of grid regions; one pixel region and a first barrier wall electrode surrounding the one pixel region are provided in each grid region.

In the array substrate provided by at least one embodiment of the present disclosure, each of the plurality of first barrier wall electrodes is in a ring shape or a planar surface shape.

In the array substrate provided by at least one embodiment of the present disclosure, each pixel electrode includes a plurality of pixel sub-electrodes, and the plurality of pixel sub-electrodes are connected to a plurality of data signal lines, respectively; each data signal line at least includes a data signal main line, and each of one or more of the plurality of data signal lines further includes a transfer electrode and a data signal auxiliary line, and the data signal auxiliary line is electrically connected to the data signal main line through the transfer electrode; a plurality of data signal main lines, extend along the second direction and are located on opposite sides of a pixel region in the first direction, and the data signal auxiliary line and the transfer electrode are located between adjacent data signal main lines in the first direction and are located between the pixel region and the second barrier wall electrode in the second direction.

### BRIEF DESCRIPTION OF DRAWINGS

In order to clearly illustrate the technical solution of the embodiments of the present disclosure, the drawings of the embodiments will be briefly described. It is obvious that the described drawings in the following are only related to some embodiments of the present disclosure and thus are not limitative of the present disclosure.

FIG. 1 illustrates a schematic cross-sectional view of an electronic paper display device.

FIG. 2A to FIG. 2D respectively illustrate schematic cross-sectional views of electronic paper display devices according to some embodiments of the present disclosure.

FIG. 3A illustrates a schematic plan view of a plurality of pixel regions and a barrier wall electrode structure in a first substrate of an electronic paper display device according to some embodiments of the present disclosure.

FIG. 3B illustrates a schematic plan view of one pixel region and a barrier wall electrode structure surrounding the pixel region in a first substrate of an electronic paper display device according to some embodiments of the present disclosure.

FIG. 3C and FIG. 3D schematically illustrate schematic plan views of an electronic barrier wall generated by a barrier wall electrode structure between two adjacent pixel regions.

FIG. 3E schematically illustrates a schematic plan view in which a barrier wall electrode in a first substrate of an electronic paper display device is connected to a signal line through a via hole.

FIG. 4 illustrates a schematic cross-sectional view of an array substrate according to some embodiments of the present disclosure.

FIG. 5 to FIG. 10B are schematic plan layout views of respective layers in the array substrate illustrated in FIG. 4 according to some embodiments of the present disclosure.

FIG. 11 illustrates a schematic cross-sectional view of an array substrate according to some other embodiments of the present disclosure.

FIG. 12 to FIG. 18B are schematic plan layout views of respective layers in the array substrate illustrated in FIG. 11 according to some embodiments of the present disclosure.

FIG. 19 illustrates a schematic cross-sectional view of an array substrate according to some further embodiments of the present disclosure.

FIG. 20 to FIG. 25B are schematic plan layout views of respective layers in the array substrate illustrated in FIG. 19 according to some embodiments of the present disclosure.

FIG. 26 illustrates a schematic cross-sectional view of an array substrate according to some further embodiments of the present disclosure.

FIG. 27 to FIG. 32B are schematic plan layout views of respective layers in the array substrate illustrated in FIG. 26 according to some embodiments of the present disclosure.

### DETAILED DESCRIPTION

In order to make objects, technical details and advantages of the embodiments of the present disclosure apparent, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the disclosure.

Unless otherwise defined, all the technical and scientific terms used herein have the same meanings as commonly understood by one of ordinary skill in the art to which the present disclosure belongs. The terms “first,” “second,” etc., used in the present disclosure are not intended to indicate any sequence, amount or importance, but distinguish different components. The terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not limited to a physical connection or mechanical connection, but may also include an electrical connection, directly or indirectly.

FIG. 1 illustrates a schematic cross-sectional view of a display device.

Referring to FIG. 1, the display device 50 is an electronic ink screen and includes a first substrate 12, a second substrate 22, a sealant 30, a pixel barrier wall 31 and a dispersant layer 45. The first substrate 12 and the second substrate 22 are disposed to face each other, and the sealant 30 and the pixel barrier wall 31 are disposed between the first substrate 12 and the second substrate 22. The sealant 30 surrounds and encloses an edge of the display device, so as to define, together with the first substrate 12 and the second substrate 22, a space where the dispersant layer 45 is located. The pixel barrier wall 31 separates the space between the first substrate 12 and the second substrate 22 into a plurality of chambers to define a plurality of pixel regions. That is, each chamber corresponds to one pixel region.

The first substrate 12 includes a base substrate 10 and a plurality of pixel electrodes 11, and the plurality of pixel electrodes 11 are disposed on a side of the base substrate 10 close to the second substrate 22. The second substrate 22 includes a base substrate 20 and a common electrode 21, and the common electrode 21 is disposed on a side of the base substrate 20 close to the first substrate 12. In each pixel region, the pixel electrode 11 and the common electrode 21 are disposed to face each other and are configured to generate an electric field in a vertical direction (i.e., a direction perpendicular to the main surface of the base substrate). In some embodiments, the dispersant layer 45 includes a dispersant 40 as well as a plurality of charged particles 41 and a plurality of charged particles 42. Charged particles 41 and 42 are dispersed in the dispersant 40 and have electrical properties opposite to each other. For example, the charged particles 41 are white particles and negatively charged, and the charged particles 42 are black particles and positively charged.

In each pixel region, an upward or downward electric field is generated between the pixel electrode 11 and the common electrode 21 by applying appropriate voltages to the pixel electrode 11 and the common electrode 21. The dashed arrow in FIG. 1 schematically illustrates the electric field lines of the electric field in each pixel. The charged particles 41 and 42 move under the action of the electric field, for example, respectively moves toward or away from the common electrode. The display side of the display device 50 is, for example, located at the side where the second substrate 22 is located. For example, when the pixel electrode 11 and the common electrode 21 generate an upward electric field, and the black charged particles move upwardly and are distributed in the visual field at the upper side of the figure, the pixel region presents a black display state; when the pixel electrode 11 and the common electrode 21 generate a downward electric field, and the white charged particles move upwardly and are distributed in the visual field at the upper side of the figure, the pixel region presents a white state display. In addition, gray scale display can be realized by controlling the aggregation degree of black and white particles at the bottom and top of the pixel region. The more black particles at the top, the lower the brightness; and the more white particles at the top, the higher the brightness.

The pixel barrier wall 31 is disposed between adjacent pixel regions to separate dispersants and charged particles in a plurality of pixel regions from each other. The pixel barrier wall 31 includes an insulating material, and can also be referred to as an insulating barrier wall or a physical barrier wall. In some embodiments, a plurality of pixel barrier walls 31 may be formed on the first substrate 12 through a patterning process, and then the first substrate 12 and the second substrate 22 are assembled into a cell. However, in the process of forming the pixel barrier wall 31, due to the limitation of process accuracy, it may be difficult to ensure a height uniformity of the pixel barrier walls 31 formed in different areas, which may lead to a crosstalk between adjacent pixel regions of the charged particles in the dispersant layer. For example, as illustrated in FIG. 1, the height of part of the pixel barrier walls 31 is lower, so that a gap may be existed between the part of pixel barrier walls 31 and the first substrate 22, and charged particles may have crosstalk between adjacent pixel regions through the gap.

Embodiments of the present disclosure provide an array substrate, an electronic paper display device including the array substrate, and a driving method thereof, in which by disposing a barrier wall electrode structure in the array substrate and by configuring the barrier wall electrode structure to form an electronic barrier wall including two opposite electric fields, the crosstalk between adjacent pixels caused by the charged particles in the dispersant layer can be effectively avoided, thereby improving the display quality of the display device.

For example, the array substrate has a plurality of pixel regions arranged in an array, and includes a base substrate, as well as a plurality of pixel electrodes and a barrier wall electrode structure disposed on a side of the base substrate. The plurality of pixel electrodes are located in the plurality of pixel regions respectively, and the barrier wall electrode structure is located between adjacent pixel regions. The plurality of pixel regions include a first pixel region and a second pixel region adjacent to each other in a first direction parallel to the main surface of the base substrate, and the plurality of pixel electrodes include a first pixel electrode and a second pixel electrode located in the first pixel region and the second pixel region respectively. The barrier wall electrode structure includes a first barrier wall electrode, a second barrier wall electrode and a third barrier wall electrode; at least part of the first barrier wall electrode, at least part of the second barrier wall electrode and at least part of the third barrier wall electrode are sequentially arranged between the first pixel region and the second pixel region in the first direction; the first barrier wall electrode and the second barrier wall electrode are configured to form a first electric field, the second barrier wall electrode and the third barrier wall electrode are configured to form a second electric field, wherein the first electric field and the second electric field are opposite in direction and are configured to jointly form an electronic barrier wall, in which the second barrier wall electrode is a common electrode shared by the first electric field and the second electric field.

For example, the driving method of the electronic paper display device includes: applying a first voltage, a second voltage and a third voltage to the first barrier wall electrode, the second barrier wall electrode and the third barrier wall electrode, respectively, wherein the first voltage is smaller than the second voltage, and the third voltage is smaller than the second voltage, so that the electronic barrier wall formed by the barrier wall electrode structure between adjacent first pixel region and second pixel region includes two electric fields with opposite directions and facing away from each other; or, the first voltage is greater than the second voltage, and the third voltage is greater than the second voltage, so that the electronic barrier wall formed by the barrier wall electrode structure between the adjacent first pixel region and second pixel region includes two electric fields with opposite directions and facing towards each other. The electronic barrier wall formed by the two electric fields can prevent from the crosstalk of charged particles between the first pixel region and the second pixel region.

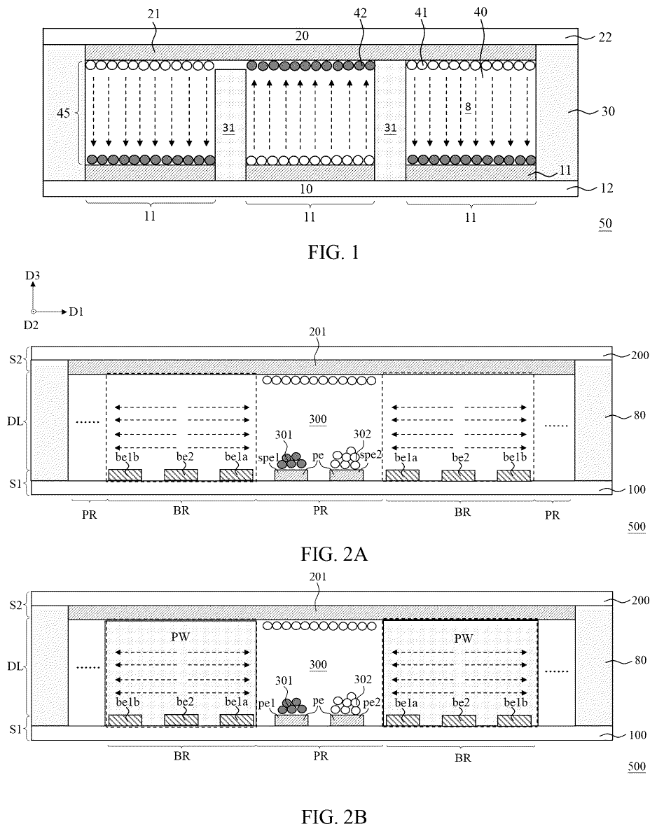

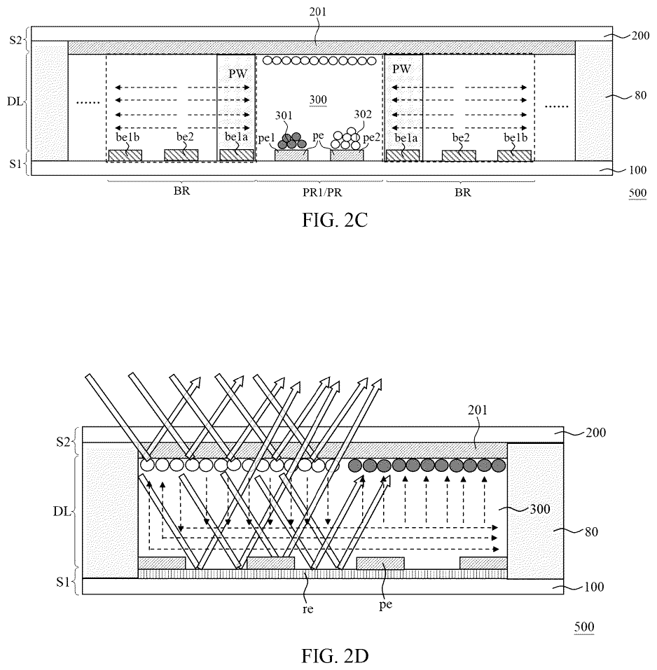

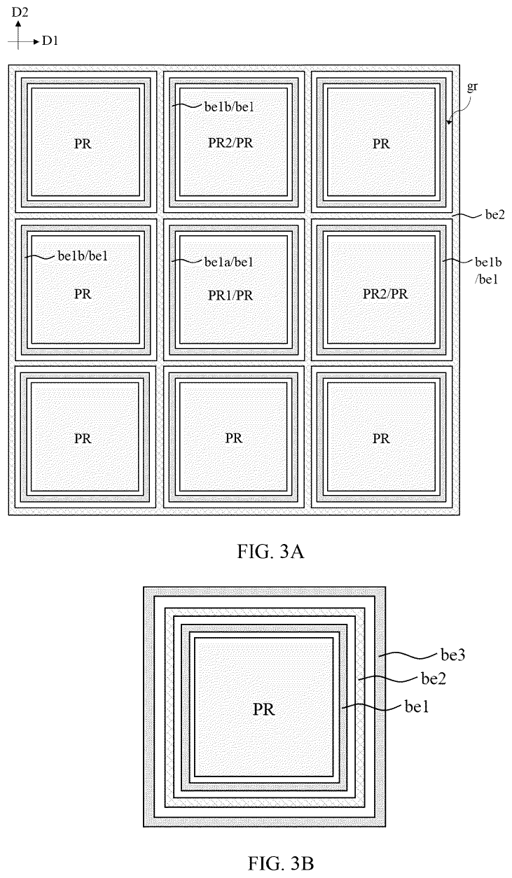

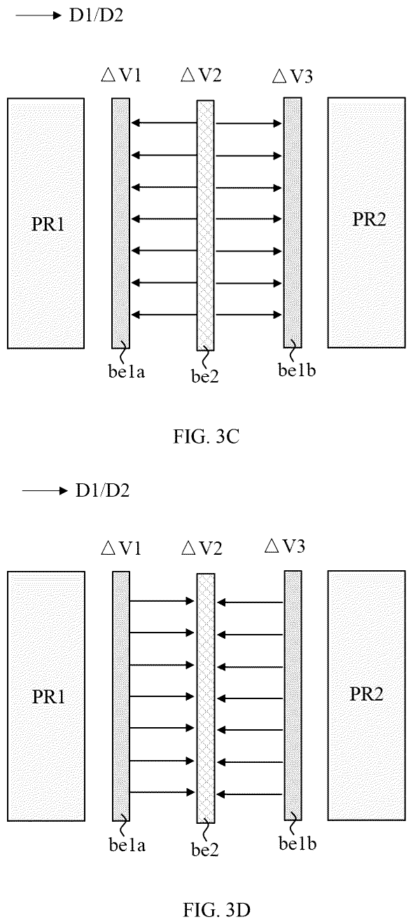

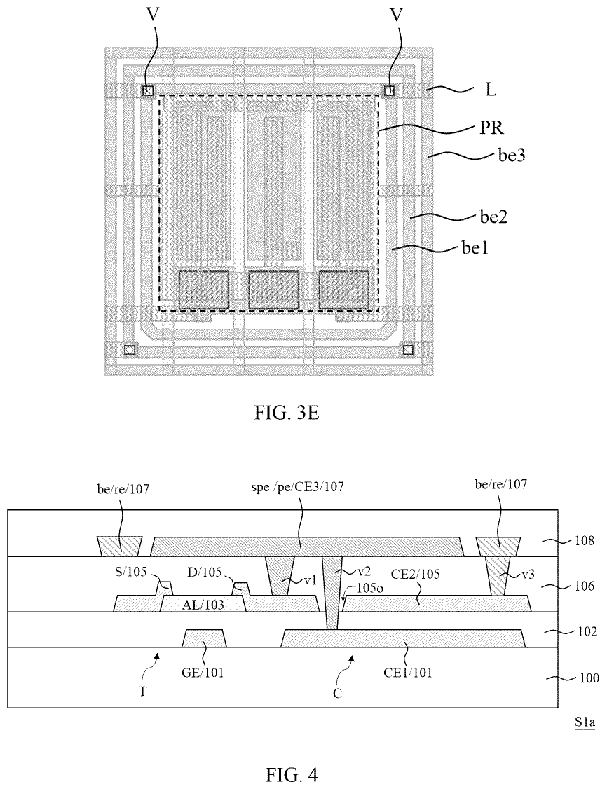

FIG. 2A to FIG. 2D illustrate schematic cross-sectional views of an electronic paper display device according to some embodiments of the present disclosure. FIG. 3A illustrates a schematic plan view of a first substrate of an electronic paper display device according to some embodiments of the present disclosure.

Referring to FIG. 2A and FIG. 3A, in some embodiments, the electronic paper display device 500 includes a pixel region PR and a barrier wall region BR, the barrier wall region BR may be located at a periphery of the pixel region PR and between adjacent pixel regions PR. For example, the electronic paper display device 500 has a first substrate S1, a second substrate S2 and a dispersant layer DL; the first substrate S1 and the second substrate S2 are disposed facing each other, and the dispersant layer DL is sandwiched between the first substrate S1 and the second substrate S2. The first substrate S1 may include a base substrate 100, as well as pixel electrodes and a barrier wall electrode structure disposed on a side of the base substrate 100 close to the second substrate S2; the second substrate S2 may include a base substrate 200 and a common electrode 201 disposed on a side of the base substrate 200 close to the first substrate S1. In some embodiments, the dispersant layer DL may include a dispersant 300 and charged particles distributed in the dispersant 300; for example, the charged particles may include at least one of a first charged particle having a first electrical property and a second charged particle having a second electrical property, and the first electrical property and the second electrical property are opposite to each other. For example, the dispersant 300 may include a plurality of charged particles 301 and a plurality of charged particles 302. Charged particles 301 and 302 have different colors and opposite electrical properties. For example, the charged particles 301 are black particles and positively charged; the charged particles 302 are white particles and negatively charged.

In some embodiments, a plurality of pixel regions PR are arranged in an array along directions parallel to the main surface of the base substrate 100 (for example, a direction D1 and a direction D2), and the barrier wall region BR may surround each pixel region PR in a direction parallel to the base substrate 100 (for example, horizontal directions including the direction D1 and the direction D2); that is, the barrier wall region BR is provided between every two adjacent pixel regions PR in the arrangement direction of the plurality of pixel regions PR. The direction D1 and the direction D2 intersect with each other, for example, they are perpendicular to each other. For simplicity of illustrations, only one pixel region PR and the barrier wall regions BR located on two sides of the pixel region in the direction D1 are illustrated in FIG. 2A. The ellipses located in the side regions of the barrier wall region BR in FIG. 2A indicate that other pixel regions and barrier wall regions may be provided in these regions. It should be understood that the number of pixel regions illustrated in FIGS. 2A and 3A is only for illustration, and the present disclosure is not limited thereto.

In each pixel region PR, the common electrode 201 and the pixel electrode pe face each other in a direction (for example, a direction D3) perpendicular to the main surface of the base substrate 100, and the pixel electrode pe may include a plurality of pixel sub-electrodes spaced apart from each other, including, for example, pixel sub-electrodes spe1 and spe2. A plurality of pixel sub-electrodes spe1 and spe2 may be configured to receive the same or different data signals to be applied with the same or different voltages. The common electrode 201 may be configured to receive a common voltage (Vcom) signal, and an electric field in the direction D3 (i.e., an electric field in the vertical direction) may be generated between the common electrode 201 and each pixel sub-electrode. In some examples, different pixel sub-electrodes spe1 and spe2 located in the same pixel region PR may receive different voltage signals, so that an electric field can also be generated between different pixel sub-electrodes; the direction of the electric field is parallel to the main surface of the base substrate, for example, may be the same as the direction D1, and may be referred to as an electric field in a horizontal direction. It should be understood that, in the present disclosure, the identified directions D1, D2 and D3 each include two opposite directions. For example, the direction D1 includes the rightward and leftward directions in the figure, the direction D3 includes the upward and downward directions in the figure, and the direction D2 includes the direction towards or away from the paper plane in FIG. 2A.

In some embodiments, in one pixel region, a plurality of electric fields generated by the common electrode and a plurality of pixel sub-electrodes can jointly form a combined electric field, and the direction and intensity of the electric field in the pixel region are controlled by controlling the voltage signals applied to the plurality of pixel sub-electrodes, thereby controlling the aggregation form of the charged particles and further controlling the display state of the pixel region. By dividing the pixel electrode in the pixel region into a plurality of pixel sub-electrodes separated from each other, and by connecting the plurality of pixel sub-electrodes with a plurality of different data signal lines respectively, each pixel sub-electrode can be independently controlled, so that the variety of the aggregation forms of the charged particles in this pixel region can be improved, and it is beneficial to accurately controlling the aggregation forms of the charged particles, thereby improving the variety and accuracy of display of the display device.

Referring to FIG. 2A and FIG. 3A, in some embodiments, in the barrier wall region between every two adjacent pixel regions, the barrier wall electrode structure includes three barrier wall electrodes, such as a first barrier wall electrode, a second barrier wall electrode and a third barrier wall electrode, which are sequentially arranged along the arrangement direction of two adjacent pixel regions. For example, a plurality of pixel regions include a first pixel region PR1 and a second pixel region PR2 arranged in the direction D1 or D2 and adjacent to each other, and the barrier wall electrode structure includes barrier wall electrodes be1a, be2 and be1b. The barrier wall electrodes be1a, be2 and be1b may be referred to as a first barrier wall electrode, a second barrier wall electrode and a third barrier wall electrode, respectively. At least part of the barrier wall electrode be1a, at least part of the barrier wall electrode be2 and at least part of the barrier wall electrode be1b are located between the first pixel region PR1 and the second pixel region PR2, and are arranged in sequence along the arrangement direction (e.g., direction D1 or D2) of the two adjacent pixel regions and are spaced apart from each other, and are configured to generate an electronic barrier wall including two electric fields with opposite directions between the two adjacent pixel regions. The arrow in FIG. 2A schematically illustrates the electric field formed by a plurality of barrier wall electrodes in the barrier wall region. FIGS. 3C and 3D schematically illustrate two opposite electric fields generated by three barrier wall electrodes between two adjacent pixel regions.

Referring to FIG. 2A, FIG. 3A, FIG. 3C and FIG. 3D, in the barrier wall region BR between every two adjacent pixel regions, at least part of each of the three barrier wall electrodes be1a, be2 and be1b may be arranged along the arrangement direction of the two adjacent pixel regions (for example, the direction D1 or D2) and spaced apart from each other. That is, the barrier wall electrodes be1a and be1b are arranged on two opposite sides of the barrier wall electrode be2 in the arrangement direction of two adjacent pixel regions. The barrier wall electrode be2 is configured to receive a voltage signal different from those of the barrier wall electrodes be1a and be1b; and the barrier wall electrode be1a and the barrier wall electrode be1b are configured to receive the same or different voltage signals. For example, the barrier wall electrodes be1a, be2 and be1b are respectively configured to receive a first voltage ΔV1, a second voltage ΔV2 and a third voltage ΔV3; the second voltage ΔV2 is different from the first voltage ΔV1 and the third voltage ΔV3; and the first voltage ΔV1 and the third voltage ΔV3 may be the same as or different from each other. For example, in some examples, the first voltage ΔV1 and the third voltage ΔV3 may both be smaller than the second voltage ΔV2 or both be greater than the second voltage ΔV2; and the first voltage ΔV1 and the third voltage ΔV3 may be the same as each other.

For example, as illustrated in FIGS. 2A and 3C, the second voltage ΔV2 may be greater than the first voltage ΔV1 and greater than the third voltage ΔV3; and the first voltage ΔV1 and the third voltage ΔV3 may be substantially the same as each other. In this way, the electronic barrier wall formed by the barrier wall electrode structure between the two adjacent pixel regions includes two electric fields with electric field directions opposite to and facing away from each other. For example, an electric field with a direction directed from the barrier wall electrode be2 to the barrier wall electrode be1a can be generated between the barrier wall electrode be1a and the barrier wall electrode be2; and an electric field with a direction directed from the barrier wall electrode be2 to the barrier wall electrode be1b can be generated between the barrier wall electrode be1b and the barrier wall electrode be2. In this example, the electric field generated by the barrier wall electrodes be1a and be2 can prevent positively charged particles in the pixel region PR1 from approaching or entering the barrier wall region BR and crossing the barrier wall region BR to cause a crosstalk with respect to the pixel region PR2, and can prevent negatively charged particles in the pixel region PR2 from approaching or entering the barrier wall region BR and crossing the barrier wall region BR to cause a crosstalk with respect to pixel region PR1. The electric field generated by the barrier wall electrodes be1b and be2 can prevent negatively charged particles in the pixel region PR1 from approaching or crossing the barrier wall region BR to cause a crosstalk with respect to the pixel region PR2, and can prevent positively charged particles in the pixel region PR2 from approaching or crossing the barrier wall region BR to cause a crosstalk with respect to the pixel region PR1. However, the present disclosure is not limited thereto.

For example, as illustrated in FIGS. 2A and 3D, the second voltage ΔV2 may be smaller than the first voltage ΔV1 and the third voltage ΔV3; and the first voltage ΔV1 and the third voltage ΔV3 may be substantially the same as each other. In this way, the electronic barrier wall formed by the barrier wall electrode structure between the two adjacent pixel regions includes two electric fields with electric filed directions opposite to and facing towards each other. For example, an electric field with a direction directed from the barrier wall electrode be1a to the barrier wall electrode be2 can be generated between the barrier wall electrode be1a and the barrier wall electrode be2; and an electric field with a direction directed from the barrier wall electrode be1b to the barrier wall electrode be2 can be generated between the barrier wall electrode be1b and the barrier wall electrode be2. In this example, the electric field generated by the barrier wall electrode be1a and the barrier wall electrode be2 can prevent negatively charged particles in the pixel region PR1 from approaching or entering the barrier wall region BR and crossing the barrier wall region BR to cause a crosstalk with respect to the pixel region PR2, and can prevent positively charged particles in the pixel region PR2 from approaching or entering the barrier wall region BR and crossing the barrier wall region BR to cause a crosstalk with respect to the pixel region PR1. The electric field generated by the barrier wall electrodes be1b and be2 can prevent the positively charged particles in the pixel region PR1 from approaching or crossing the barrier wall region BR to cause a crosstalk with respect to the pixel region PR2, and can prevent the negatively charged particles in the pixel region PR2 from approaching or crossing the barrier wall region BR to cause a crosstalk with respect to the pixel region PR1.

In the embodiment of the present disclosure, because a plurality of barrier wall electrodes disposed in the barrier wall region between adjacent pixel regions generate an electronic barrier wall including two opposite electric fields, the electronic barrier wall can effectively prevent charged particles in each pixel region from approaching or crossing the barrier wall region and resulting in a crosstalk with respect to other adjacent pixel regions regardless of whether the charged particles in the pixel region are positively charged and/or negatively charged. Specifically, charged particles 301 with a first electrical property (for example, positive electricity) can be prevented by one of the two opposite electric fields from approaching or crossing the barrier wall region to have a crosstalk with respect to other pixel regions, and charged particles 302 with a second electrical property (for example, negative electricity) can be prevented by the other one of the two opposite electric fields from approaching or crossing the barrier wall region to have a crosstalk with respect to other pixel regions.

It should be noted that, the electric field lines in each of FIG. 2A, FIG. 3C and FIG. 3D are illustrated to have exactly opposite directions, which are exactly identical to the arrangement direction of the adjacent pixel regions. However, this is only an illustration, and the present disclosure is not limited thereto. In some embodiments, in the barrier wall region BR, a plurality of barrier wall electrodes and the common electrode 201 of the second substrate S1 also face each other in a direction perpendicular to the main surface of the base substrate 100. In addition to generating an electric field in the horizontal direction (i.e., a direction parallel to the main surface of the base substrate) by applying voltage signals to the corresponding barrier wall electrodes, an electric field in the vertical direction (i.e., a direction perpendicular to the main surface of the base substrate) can also be generated between one or more barrier wall electrodes and the common electrode 201. The horizontal electric field and the vertical electric field generate a combined electric field, and at least one component of the combined electric field can be the same as the arrangement direction of adjacent pixel regions. For example, the direction of the combined electric field (first electric field) generated by the barrier wall electrode be1a, the barrier wall electrode be2 and the common electrode 201 may be obliquely upward or downward, and has a horizontally leftward or rightward component (here, the leftward and rightward directions are the directions illustrated in the figure); the direction of the combined electric field (second electric field) generated by the barrier wall electrode be1b, the barrier wall electrode be2 and the common electrode 201 may be obliquely upward or downward, and has a rightward or leftward component; that is, at least one component of a first electric field direction (for example, a component in a direction parallel to the main surface of the base substrate) and at least one component of a second electric field direction (for example, a component in a direction parallel to the main surface of the base substrate) are opposite to each other in directions. Therefore, in the present disclosure, two opposite electric fields include the case that the directions of the two electric fields are completely opposite (for example, as illustrated in the figure), and also include the case that at least one component (for example, a component parallel to the main surface of the base substrate) of one electric field is opposite to at least one component (for example, a component parallel to the main surface of the base substrate) of the other electric field. In various embodiments of the present disclosure, at least one component of the first electric field direction and at least one component of the second electric field direction included in the electronic barrier wall between every two adjacent pixel regions are opposite to each other, and are the same as the arrangement direction of the two adjacent pixel regions.

It should be understood that, the above embodiment describes the case where the pixel region includes charged particles with two opposite electrical properties at the same time by way of example, but the present disclosure is not limited thereto. In an alternative embodiment, the pixel region may also include charged particles with only one electrical property. For example, only negatively charged white particles may be included in the pixel region, and a black light absorbing layer is correspondingly disposed in the first substrate; in this case, the electronic barrier walls illustrated in FIGS. 3C and 3D may also be adopted, and the electronic barrier wall illustrated in FIG. 3D may be preferred. Alternatively, the pixel region may only include positively charged black particles, and the first substrate is correspondingly provided with a reflective layer; in this case, the electronic barrier walls illustrated in FIGS. 3C and 3D may also be adopted, and the electronic barrier wall illustrated in FIG. 3C may be preferred.

Referring to FIGS. 2A and 3A, in some embodiments, the plurality of pixel regions PR are arranged in an array in a direction parallel to the main surface of the base substrate 100, for example, arranged in a plurality of rows along the direction D1 and in a plurality of columns along the direction D2. It should be noted that, FIG. 3A only briefly illustrates the outer contour of the pixel region PR, and does not specifically illustrate a plurality of pixel sub-electrodes located in the pixel region. For example, each pixel region PR is surrounded by a barrier wall electrode be1 in a direction parallel to the main surface of the base substrate (the direction includes the arrangement direction of the pixel regions), and each barrier wall electrode be1 is surrounded by a barrier wall electrode be2 in a direction parallel to the main surface of the base substrate (the direction includes the arrangement direction of the pixel regions). In this way, a barrier wall electrode be2 and barrier wall electrodes be1 located at opposite sides of the barrier wall electrode be2 in the arrangement direction of two adjacent pixel regions are arranged between any two adjacent pixel regions, so that the barrier wall electrode structure can generate an electronic barrier wall constituted by two opposite electric fields between any two adjacent pixel regions.

The plurality of barrier wall electrodes be1 may be arranged in one-to-one correspondence with the plurality of pixel regions PR, and the plurality of barrier wall electrodes be1 are spaced apart from each other by the barrier wall electrode be2. For two adjacent pixel regions (for example, a first pixel region and a second pixel region adjacent in the direction D1 or D2), the barrier wall electrode be1 surrounding the first pixel region and the barrier wall electrode be1 surrounding the second pixel region can be used as the barrier wall electrode be1a and the barrier wall electrode be1b in FIGS. 2A and 3C, respectively, or vice versa. In some embodiments, the barrier wall electrode be2 may be referred to as a second barrier wall electrode; and the barrier wall electrode be1a and the barrier wall electrode be1b may be referred to as a first barrier wall electrode and a third barrier wall electrode, respectively; or vice versa. Alternatively, all the barrier wall electrodes be1 may be referred to as first barrier wall electrodes.

In some embodiments, the barrier wall electrode be1 may be in a grid shape and define a plurality of grid regions gr; the pixel regions PR and the barrier wall electrodes be1 may be disposed in one-to-one correspondence with the grid regions gr, so that one pixel region PR (that is, one pixel electrode pe) and the barrier wall electrode be1 surrounding the pixel region PR are disposed in each grid region gr. In the present disclosure, the grid region refers to the hollow region surrounded and enclosed by the electrode part of the grid-shaped barrier wall electrode. For example, the barrier wall electrode includes a plurality of electrode strips extending in the direction D1 and parallel to each other, and a plurality of electrode strips extending in the direction D2 and parallel to each other; and the plurality of electrode strips extending in the direction D1 intersect with the plurality of electrode strips extending in the direction D2 to form a grid shape and define a plurality of grid regions gr. The plurality of electrode strips of the barrier wall electrode be2 may also be referred to as grid lines of the grid-shaped electrode. In other words, the barrier wall electrode be1 has a plurality of ring-shaped portions, and the inner side wall of each ring-shaped portion defines one grid region gr and surrounds the barrier wall electrode be1 and the pixel region PR located in the grid region gr.

FIG. 3B illustrates a schematic plan view of a pixel region and a barrier wall region surrounding the pixel region according to some other embodiments of the present disclosure.

Referring to FIG. 3B, in some embodiments, three ring-shaped barrier wall electrodes be1, be2 and be3 are disposed around the pixel region PR. The barrier wall electrodes be1, be2 and be3 are spaced apart from each other, and the distances from the barrier wall electrodes be1, be2 and be3 to the pixel region PR sequentially increase. For example, the pixel region PR is surrounded by the barrier wall electrode be1, the barrier wall electrode be1 is surrounded by the barrier wall electrode be2, and the barrier wall electrode be2 is surrounded by the barrier wall electrode be3.

In some embodiments, the structure illustrated in FIG. 3B is substantially equivalent to the structure illustrated in FIG. 3A. For example, taking the pixel region PR located at the central position in FIG. 3A as an example, the barrier wall electrodes be1 and be2 directly surrounding the pixel region PR are equivalent to the barrier wall electrodes be1 and be2 illustrated in FIG. 3B, while the barrier wall electrodes be1 located around other adjacent pixel regions PR at the periphery of this pixel region PR respectively have parts facing the barrier wall electrode be2 and collectively form a barrier wall electrode in a shape like a ring; the barrier wall electrode in a shape like a ring is substantially equivalent to the barrier wall electrode be3 illustrated in FIG. 3B.

As can be seen from FIG. 3A to FIG. 3D, for each pixel region PR, three barrier wall electrodes are disposed between the pixel region PR and each adjacent pixel region. The three barrier wall electrodes are configured to generate two electric fields with opposite directions, so that crosstalk of charged particles between adjacent pixel regions in the pixel regions can be avoided.

In some embodiments, applying voltage signals to the respective barrier wall electrodes in the barrier wall electrode structure may include: connecting the edge of the corresponding barrier wall electrode (for example, the part located at the edge of the display region) to a signal line disposed at the same layer, so as to apply the voltage signal to the corresponding barrier wall electrode through the signal line; or it may also include: connecting the barrier wall electrode to a signal line located in a different layer through a via hole, so as to apply the corresponding voltage signal to the barrier wall electrode through the signal line and the via hole. For example, in the barrier wall structure illustrated in FIG. 3A, for the barrier wall electrode be2, a portion of the barrier wall electrode be2 located at the edge of the display region may be connected to a voltage signal line (not illustrated) to receive the corresponding voltage signal, while the barrier wall electrode be1 may be connected to a voltage signal line located at another layer through a via hole to receive the corresponding voltage signal. FIG. 3E schematically illustrates that the corresponding barrier wall electrode is connected to a signal line L at a different layer through a via hole V, and the signal line L is configured to apply a voltage signal to the barrier wall electrode. It should be understood that, the embodiment of the present disclosure does not limit the way that the respective barrier wall electrodes receive the voltage signals, as long as the barrier wall electrode structure can receive corresponding voltage signals to form an electronic barrier wall.

In some embodiments, as illustrated in FIG. 2A, because the electronic barrier wall formed by the barrier wall electrode structure can effectively prevent the crosstalk of charged particles between adjacent pixel regions, a physical barrier wall (or insulating barrier wall) can be omitted. That is, the display device 500 may not include a physical barrier wall disposed between the first substrate S1 and the second substrate S2 and between adjacent pixel regions. For example, the dispersant 300 may also be located in the barrier wall region BR, that is, it may be located in a region overlapping with the barrier wall electrode structure in the direction perpendicular to the main surface of the base substrate 100. Moreover, due to the electronic barrier wall generated by the barrier wall electrode structure, the charged particles located in the pixel region PR would substantially not cross to the dispersant 300 located in the barrier wall region BR. Therefore, the crosstalk of charged particles can be effectively prevented only by the electronic barrier wall formed by the barrier wall electrode structure. However, the present disclosure is not limited thereto.

In some other embodiments, in the barrier wall region BR, in addition to the electronic barrier wall constituted by a plurality of barrier wall electrodes, there may also be a physical barrier wall, and the region where the physical barrier wall is located may or may not overlap with the region where the electronic barrier wall is located. For example, at least part of the physical barrier wall may be disposed in the region where the electronic barrier wall is located, and may overlap or not overlap with the barrier wall electrode in the direction perpendicular to the main surface of the base substrate; for example, the physical barrier wall may overlap with one or more barrier wall electrodes in the barrier wall electrode structure in the direction perpendicular to the main surface of the base substrate.

FIG. 2B and FIG. 2C are schematic cross-sectional views of display devices according to some other embodiments of the present disclosure, illustrating some examples in which both a physical barrier wall and an electronic barrier wall are included in the barrier wall region. In some embodiments, a physical barrier wall PW is further arranged in the barrier wall region BR, and the physical barrier wall PW is disposed between the first substrate S1 and the second substrate S2 in the direction perpendicular to the main surface of the base substrate, and between adjacent pixel regions in the direction parallel to the main surface of the base substrate.

Referring to FIG. 2B, in some embodiments, the physical barrier wall PW has a size (e.g., width, area, etc.) larger than that of a single barrier wall electrode in a direction parallel to the base substrate 100 (e.g., direction D1 and/or direction D2), and the physical barrier wall PW overlaps with a plurality of barrier wall electrodes in a direction D3 perpendicular to the base substrate 100. For example, the physical barrier wall PW may cover the sidewalls of the barrier wall electrodes be1a, be2 and be1b and the surfaces thereof away from the base substrate 100, and may fill the gaps between adjacent barrier wall electrodes, and extend towards the second substrate S2 to be close to or in contact with the common electrode 201.

Referring to FIG. 2C, in some other embodiments, the physical barrier wall PW has a size (e.g., width, area, etc.) smaller than or larger than that of a single barrier wall electrode in a direction parallel to the base substrate 100 (e.g., direction D1 and/or direction D2), and the physical barrier wall PW overlaps with a part of the barrier wall electrode in a direction perpendicular to the base substrate 100. For example, the physical barrier wall PW may be located on the barrier wall electrode be1a, covering the sidewall of the barrier wall electrode be1a and the surface thereof at the side away from the base substrate 100, and extending towards the second substrate S2 to be close to or in contact with the common electrode 201. In this example, the physical barrier wall PW is disposed on the barrier wall electrode be1a close to the pixel region. In some other examples, the physical barrier wall PW may also be disposed on the barrier wall electrode be2 or be1b, or on any two of the three barrier wall electrodes, or disposed in the gap between adjacent barrier wall electrodes.

In some embodiments, the physical barrier wall PW is located between the first substrate 100 and the second substrate 200 in the direction perpendicular to the main surface of the base substrate 100, and extends from the barrier wall region BR of the first substrate 100 (e.g., a position on the barrier wall electrode) to a position close to or in contact with the common electrode 201 of the second substrate S2. In the embodiment of the present disclosure, because an electronic barrier wall with two opposite electric fields is provided, charged particles located in the pixel regions PR can be prevented from approaching or crossing the barrier wall region. Thus, even if the height of the physical barrier wall PW is uneven, the charged particles in the pixel region can still be prevented from crossing the barrier wall region and resulting in crosstalk with respect to other pixel regions. Moreover, in the barrier wall region, the electronic barrier wall and the physical barrier wall are used to collectively form the barrier wall structure, which can jointly block the charged particles, thus providing double protection and improving the ability of the barrier wall structure to prevent crosstalk of charged particles in adjacent pixel regions.

FIG. 2D illustrates a schematic cross-sectional view of an electronic paper display device according to some other embodiments of the present disclosure. The solid arrow in FIG. 2D schematically illustrates the state that light is reflected after being irradiated on the display device, and the dashed arrow schematically illustrates the direction of electric field lines.

Referring to FIG. 2D, in some embodiments, the electronic paper display device may further include a reflective electrode re, which may be located laterally aside the pixel electrode pe in the direction parallel to the main surface of the base substrate 100; the reflective electrode re may also overlap with the pixel electrode pe in the direction perpendicular to the main surface of the base substrate 100. The reflective electrode re may be located in the pixel region and/or the barrier wall region. The reflective electrode can reflect light incident from the display side. For example, a part of the light from the display side is irradiated on the white particles and is reflected by the white particles; a part of the light passes through the white particles and is irradiated on the reflective electrode, and is reflected by the reflective electrode, so that secondary reflection can be realized, thereby enhancing the white state display of the pixel region. For example, in the pixel region, the plurality of pixel sub-electrodes of the pixel electrode pe are spaced apart from each other, and the reflective electrode re may be disposed laterally aside the pixel sub-electrodes in the direction parallel to the main surface of the base substrate 100, and may be disposed in the gap between adjacent pixel sub-electrodes. For example, the reflective electrode re may be disposed between adjacent pixel electrodes of adjacent pixel regions. In some embodiments, the reflective electrode re and the pixel electrode pe may be disposed in different layers, and the reflective electrode re and the pixel electrode pe may overlap in the direction perpendicular to the main surface of the base substrate 100, but the present disclosure is not limited thereto. In some other embodiments, the reflective electrode re may also be disposed at the same layer as the pixel electrode pe.

Referring to FIG. 2A to FIG. 2D, an encapsulation frame 80 is further disposed between the edges of the first substrate S1 and the second substrate S2. The encapsulation frame 80, together with the first substrate S1 and the second substrate S2, defines the space where the dispersant layer DL is located.

FIG. 4 illustrates a schematic cross-sectional view of an array substrate according to some embodiments of the present disclosure, which can be used as the first substrate in an electronic paper display device.

Referring to FIG. 4, the array substrate Sla may include a plurality of pixel regions arranged in an array in a display region, each pixel region is provided with a pixel electrode, and the array substrate Sla includes a driving circuit connected with the pixel electrode. For example, in each pixel region, the pixel electrode may include a plurality of pixel sub-electrodes, and each pixel sub-electrode is connected to a corresponding driving circuit. The driving circuit may include one or more transistors and capacitors. Each transistor includes a gate electrode, a gate insulating layer, an active layer, a source electrode and a drain electrode, and each capacitor includes at least two electrode plates, such as a first electrode plate and a second electrode plate, which are disposed facing each other. The pixel sub-electrode of each pixel electrode is electrically connected with one of the source electrode and the drain electrode of the corresponding transistor, and is electrically connected with the electrode plate (such as the first electrode plate or the second electrode plate) of the corresponding capacitor.

It should be noted that in the present disclosure, “pixel region” refers to an effective display region, that is, the region where charged particles are controlled by the pixel electrode and the common electrode in the electronic paper display device, which is substantially the region where the pixel electrode is located. The orthographic projection of the outer contour of the pixel region on the base substrate may be substantially coincident with the orthographic projection of the outer contour of the pixel electrode on the base substrate; or, the orthographic projection range of the pixel region is slightly larger than the orthographic projection range of the pixel electrode, and the orthographic projection of the pixel electrode is located in the orthographic projection range of the pixel region. In the case where the pixel electrode includes a plurality of pixel sub-electrodes, the pixel region includes the regions where the plurality of pixel sub-electrodes are located and the regions where gaps between the plurality of pixel sub-electrodes are located. The outer contour of the pixel electrode is formed by connecting the outer contours of the plurality of pixel sub-electrodes away from each other, and the orthographic projection of the pixel region on the main surface of the base substrate is substantially coincident with the orthographic projections of the plurality of pixel sub-electrodes and the gaps therebetween on the main surface of the base substrate.

For example, the array substrate Sla may include a base substrate 100, a transistor T, a capacitor C, a pixel electrode pe, and a barrier wall electrode structure be. The transistor T may include a gate electrode GE, an active region AL, a source electrode S, a drain electrode D, and a gate insulating layer; the source electrode S and the drain electrode D are interchangeable with each other, and can be collectively referred to as the source/drain electrodes S/D. That is, the source electrode S and the drain electrode D described in the figure can also be used as a drain electrode D and a source electrode S, respectively. The capacitor C may at least include an electrode plate CE1 and an electrode plate CE2 facing each other, and an inter-electrode insulating layer. In some embodiments, the electrode plate CE1 and the electrode plate CE2 may also be referred to as a first electrode plate and a second electrode plate, respectively.

For example, the array substrate Sla may include a conductive layer 101, an insulating layer 102, an active layer 103, a conductive layer 105, an insulating layer 106, an electrode layer 107, and a passivation layer 108, which are disposed on a side of the base substrate 100. The conductive layer 101, the insulating layer 102, the active layer 103, the conductive layer 105, the insulating layer 106 and the electrode layer 107 may also be referred to as a first conductive layer, a first insulating layer, a second conductive layer, a second insulating layer and a first electrode layer, respectively. The conductive layer 101 is disposed on the base substrate 100, and may include a metal material such as copper, aluminum, molybdenum, titanium, or the like. The insulating layer 102 is disposed on the base substrate 100, and covers the side wall of the conductive layer 101 and the surface thereof at the side away from the base substrate 100. The insulating layer 102 may include an insulating material such as silicon oxide, silicon nitride, silicon oxynitride, or the like. The active layer 103 and the conductive layer 105 are located on a side of the insulating layer 102 away from the base substrate 100, and a portion of the conductive layer 105 covers a portion of the surface of the active layer 103. The active layer 103 may include an active material, such as low-temperature polysilicon, Indium Gallium Zinc Oxide (IGZO), or the like, and the conductive layer 105 may include a metal material such as copper, aluminum, molybdenum, titanium, or the like. The insulating layer 106 is disposed on the insulating layer 102, and covers the active layer 103 and the conductive layer 105. The insulating layer 106 may include an insulating material, such as silicon oxide, silicon nitride, silicon oxynitride, or the like. The electrode layer 107 is located on a side of the insulating layer 106 away from the base substrate 100. The electrode layer 107 may include a metal oxide such as indium tin oxide (ITO), or a metal oxide including a metal dopant, and the metal dopant may include a metal with reflective properties. For example, the electrode layer 107 may include indium tin oxide doped with silver, but the present disclosure is not limited thereto. The passivation layer 108 is disposed on the insulating layer 106, and covers the sidewall of the electrode layer 107 and the surface thereof at the side away from the base substrate 100. The passivation layer 108 includes, for example, an insulating material such as silicon nitride.

In some embodiments, the gate electrode GE of the transistor T, and one of the first and second electrode plates of the capacitor C (for example, the first electrode plate CE1) are disposed at the same layer, for example, both of them are disposed at the conductive layer 101. The active region AL of the transistor T is disposed at the active layer 103; the source/drain electrodes S/D of the transistor T may be disposed at the same layer as the other one (e.g., the second electrode plate CE2) of the first and second electrode plates of the capacitor C, for example, both of them are disposed at the conductive layer 105. In each transistor T, the active layer 103 and the gate electrode GE overlap with each other in the direction perpendicular to the main surface of the base substrate 100, and a part of the insulating layer 102 is located between the active layer 103 and the gate electrode GE, and serves as the gate insulating layer of the transistor T; the source electrode S and the drain electrode D each cover the sidewall of the active layer 103 and a part of the surface of the active layer 103 away from the base substrate 100. In each capacitor C, the first electrode plate CE1 and the second electrode plate CE2 overlap with each other in the direction perpendicular to the main surface of the base substrate 100, and a part of the insulating layer 102 is located between the first electrode plate CE1 and the second electrode plate CE2 and serves as an inter-electrode insulating layer of the capacitor C.

In some embodiments, a plurality of pixel sub-electrodes spe of a plurality of pixel electrodes pe are disposed at the electrode layer 107; the barrier wall electrode structure be may be disposed at the same layer as the plurality of pixel electrodes pe, for example, all of them are disposed at the electrode layer 107 and are spaced apart from each other. The barrier wall electrode structure be may also be multi-used as a reflective electrode re. That is, the pixel electrode pe, the barrier wall electrode structure be, and the reflective electrode re may all be disposed at the same layer of the electrode layer 107. For simplicity of the illustration, only one pixel sub-electrode, as well as the transistor, the capacitor, the barrier wall electrode and the like corresponding thereto are illustrated in FIG. 4. It should be understood that the other pixel sub-electrodes have similar cross-sectional structures. Herein, a plurality of components being disposed at the same layer means that the plurality of components can be formed from the same material layer by the same one patterning process.

In some embodiments, the pixel sub-electrode spe may extend through the insulating layer 106 so as to be electrically connected to one of the source electrode and drain electrode (e.g., the drain electrode D) of the transistor T, and may extend through the insulating layer 106, the conductive layer 105 and the insulating layer 102 so as to be electrically connected to the conductive layer 101, for example, to be electrically connected to the first electrode plate CE1 located at the conductive layer 101. For example, a via hole v1 is provided in the insulating layer 106, and the pixel sub-electrode spe is electrically connected to the source electrode S or the drain electrode D (e.g., the drain electrode D) of the transistor T through the via hole v1; a via hole v2 is provided in the insulating layers 106 and 102, and the pixel sub-electrode spe is electrically connected to the first electrode plate CE1 through the via hole v2. For example, an opening 1050 is provided in the conductive layer 105, and at least part of the opening 1050 overlaps with the first electrode plate CE1 in the direction perpendicular to the main surface of the base substrate. The opening 1050 may be located in or include a gap between the second electrode plate CE2 and the source/drain electrodes S/D, and the via hole v2 passes through the opening 1050 and is spaced apart from the conductive layer 105. That is, the via hole v2 extends from the surface of the insulating layer 106 away from the base substrate 100, through the insulating layer 106, through the opening 1050 of the conductive layer 105, and then through the insulating layer 102 to expose a part of the surface of the first electrode plate CE1, so that the pixel sub-electrode spe is electrically connected to the first electrode plate CE1 through the via hole v2. That is, a portion of the pixel sub-electrode spe in the via hole v2 is located in the opening 1050 of the conductive layer 105 and is spaced apart from the conductive layer 105.

In some embodiments, at least part of the pixel sub-electrode spe and the second electrode plate CE2 may overlap with each other in a direction perpendicular to the main surface of the base substrate 100; that is, the orthographic projection of the pixel sub-electrode spe on the base substrate overlaps with the orthographic projection of the second electrode plate CE2 on the base substrate. That is to say, the pixel sub-electrode spe is electrically connected to the first electrode plate CE1 of the capacitor CE1 and is disposed facing the second electrode plate CE2; therefore, the pixel sub-electrode spe can also be multi-used as a third electrode plate CE3 of the capacitor C, and a portion of the insulating layer 106 located between the second electrode plate CE2 and the pixel sub-electrode spe can be used as an inter-electrode insulating layer. That is, the capacitor C includes a first electrode plate CE1, a second electrode plate CE2, a third electrode plate CE3, and inter-electrode insulating layers 102 and 106. The second electrode plate CE2 is located between the first electrode plate CE1 and the third electrode plate CE3 in the direction perpendicular to the main surface of the base substrate 100; and the first electrode plate CE1 and the third electrode plate CE3 are electrically connected to each other. In this way, the capacitor C includes double-layer capacitance formed between the first electrode plate CE1 and the second electrode plate CE2 and between the second electrode plate CE2 and the third electrode plate CE3, so that the capacitance area can be increased and the capacitance of the capacitor C can be improved.

In some embodiments, the second electrode plate CE2 may be configured to receive a common voltage (Vcom) signal, and the second electrode plate CE2 may also be multi-used as a signal shielding structure to shield a signal crosstalk to the pixel electrode pe caused by signals (e.g., gate signals) from layers underlying thereof.

In some embodiments, a part (e.g., the first barrier wall electrode) of the barrier wall electrodes in the barrier wall electrode structure be may pass through the insulating layer 106 to be electrically connected to the conductive layer 105, and configured to be connected with a Vcom signal. For example, the insulating layer 106 has a via hole v3, and the part of the barrier wall electrodes in the barrier wall electrode structure be is electrically connected to the second electrode plate CE2 through the via hole v3 and is configured to receive a Vcom signal. In some embodiments, the via hole v1, the via hole v2 and the via hole v3 may be referred to as a first via hole, a second via hole and a third via hole, respectively.

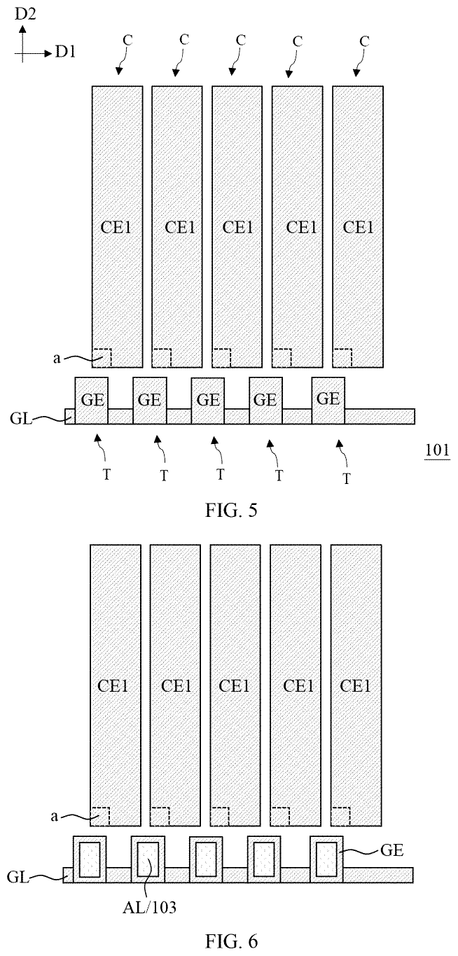

FIGS. 5 to 9B illustrate schematic plan layouts of respective layers and/or multiple layer stacks of the array substrate S1a illustrated in FIG. 4 according to some embodiments of the present disclosure. For the sake of simplicity, only one pixel region and the barrier wall region surrounding the pixel region are illustrated in FIGS. 5 to 9B. In some embodiments, in each pixel region, each pixel electrode includes a plurality of pixel sub-electrodes, each pixel sub-electrode is connected to corresponding transistor(s) and corresponding capacitor(s), each transistor is connected to a corresponding data signal line, and the data signal line is configured to apply a data signal to the corresponding pixel sub-electrode through the transistor. That is, a plurality of pixel sub-electrodes are respectively connected to a plurality of data signal lines. For example, the pixel sub-electrodes can be disposed in one-to-one correspondence with transistors, capacitors and data signal lines. For example, in this example, in a single pixel region, the pixel electrode includes five pixel sub-electrodes, and correspondingly, the array substrate includes five transistors, five capacitors, and five data signal lines that are disposed corresponding to the five pixel sub-electrodes. However, the present disclosure is not limited thereto.

FIG. 5 illustrates a schematic plan layout of the conductive layer 101 in the array substrate S1a. The conductive layer 101 includes a plurality of gate electrodes GE, a plurality of electrode plates CE1, and further includes a gate signal line GL. The plurality of gate electrodes GE may be spaced apart from each other and correspond to a plurality of transistors T, respectively. The plurality of transistors T may be arranged in a row along the direction D1. For example, the plurality of gate electrodes GE may be arranged in a row along the direction D1, and the gate signal line GL is electrically connected with a plurality of gate electrodes GE located in the same row, so as to be configured to apply a scanning signal to the plurality of gate electrodes GE in this row. The plurality of electrode plates CE1 are spaced apart from each other, and correspond to a plurality of capacitors C, respectively. The plurality of electrode plates CE1 are also spaced apart from the gate electrodes GE and the gate electrode line GL. In some embodiments, there is a connection region a in each electrode plate CE1 used for an electrical connection with a subsequent pixel electrode.

FIG. 6 illustrates a schematic layout of a stack of the conductive layer 101 and the active layer 103. The active layer 103 includes a plurality of active regions AL corresponding to a plurality of transistors respectively; and each active region AL overlaps with the corresponding gate electrode GE in the direction perpendicular to the main surface of the base substrate. For example, the orthographic projection of the active region AL on the base substrate is located within the orthographic projection range of the corresponding gate electrode GE on the base substrate, but the present disclosure is not limited thereto.

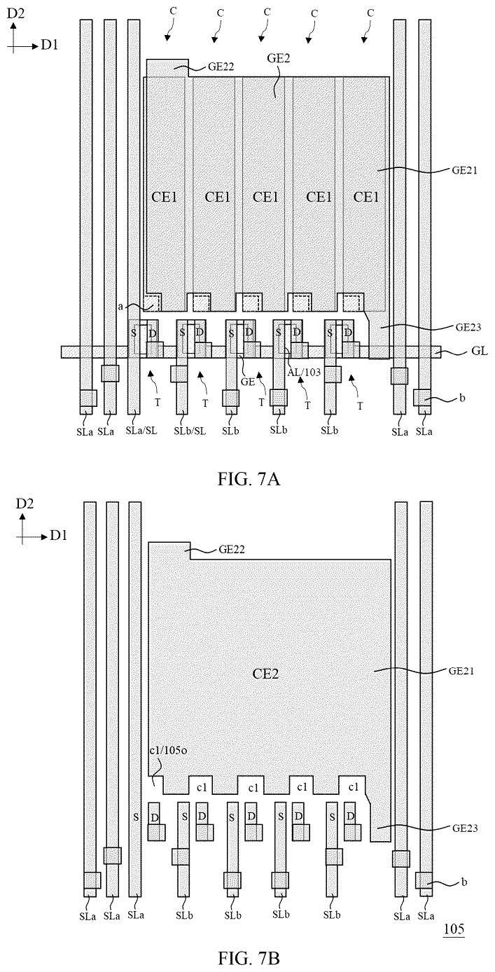

FIG. 7A illustrates a schematic layout of a stack of the conductive layer 101, the active layer 103 and a conductive layer 105; FIG. 7B illustrates a schematic layout of the conductive layer 105.

Referring to FIGS. 7A and 7B, the conductive layer 105 includes source electrodes S and drain electrodes D of a plurality of transistors, data signal lines SL, and second electrode plates CE2 of a plurality of capacitors C. In each transistor T, the source electrode S and the drain electrode D each cover a part of the corresponding active region AL, and may overlap with the corresponding gate electrode GE; one of the source electrode and the drain electrode, such as the source electrode S, is connected to the data signal line SL. In the present disclosure, unless otherwise defined, the overlapping of multiple components described with reference to the plane layout refers to the overlapping of the multiple components in a direction perpendicular to the main surface of the base substrate, that is, the orthographic projections of the multiple components on the main surface of the base substrate overlap with each other; the positional relationship between the respective components illustrated in the plan layout may include or be equivalent to the positional relationship between the orthographic projections of these components on the main surface of the base substrate.

In some embodiments, among a plurality of data signal lines, each data signal line SL includes at least a data signal main line SLa, and one or more of the plurality of data signal lines may each further include a data signal auxiliary line SLb and a transfer electrode. The data signal main line SLa and the data signal auxiliary line SLb may be electrically connected to each other through the transfer electrode. The data signal main line SLa and the data signal auxiliary line SLb may be disposed at the same layer of the conductive layer 105, while the transfer electrode may be disposed at a different layer, but the present disclosure is not limited thereto. For example, a plurality of data signal main lines SLa may extend substantially parallel to each other along the direction D2, and are arranged laterally aside (e.g., on two opposite sides of) a plurality of transistors in the direction D1. The data signal line SL connected to the source electrode S of the transistor located at the end (for example, the left end in the figure) may only include a data signal main line SLa which is directly connected with the corresponding source electrode S. For example, a part of the data signal main line SLa serves as the source electrode S of the corresponding transistor, and the data signal line SL may not need a data signal auxiliary line. Herein, the transistor located at the end refers to the transistor that is among a plurality of transistors disposed corresponding to the same pixel region and is located at the end in the arrangement direction of the plurality of transistors.

In some embodiments, the data signal lines SL of one or more transistors each include a data signal main line SLa and a data signal auxiliary line SLb, which may be electrically connected through a transfer electrode provided in a subsequent electrode layer. Each data signal auxiliary line SLb may be directly connected with the source electrode S of the corresponding transistor, for example, a part of the data signal auxiliary line SLb serves as the source electrode S of the transistor. The data signal main line SLa corresponding to each data signal auxiliary line SLb is disposed outside the region where the transistor is located.

In some embodiments, each drain electrode D has a connection region (the block region illustrated in the figure), which is configured to be electrically connected with a pixel sub-electrode in a subsequent electrode layer. When the data signal line SL includes a data signal main line SLa and a data signal auxiliary line SLb, the data signal main line SLa and the data signal auxiliary line SLb have corresponding connection regions (e.g., the block areas illustrated in the figure), that are configured to be electrically connected with a subsequent transfer electrode. In the respective components, the size of the connection region may be larger than that of other regions to provide a larger connection window, which is beneficial to the electrical connection with other components. The connection region of each component can be integrally formed with other regions.

In the conductive layer 105, the electrode plate CE2 is spaced apart from the source electrode S, the drain electrode D, the data signal line SL and the drain signal line DL. In the direction D1, the electrode plate CE2, the source and drain electrodes S and D of a plurality of transistors T, and the data signal auxiliary lines SLb are all located laterally aside a plurality of data signal main lines SLa, for example, located between the data signal main lines SLa. In the direction D2, the electrode plate CE2 is located at one side of the source and drain electrodes S and D of a plurality of transistors T and the data signal auxiliary lines SLb, and is spaced apart from these components of the plurality of transistors T. The electrode plate CE2 is disposed facing a plurality of electrode plates CE1 in the direction perpendicular to the main surface of the base substrate, and may be an integrally formed, continuous electrode; that is, the plurality of first electrode plates CE1 of the plurality of capacitors C are spaced apart from each other, and the second electrode plates CE2 of the plurality of capacitors C may share the same one electrode plate.

In some embodiments, the electrode plate CE2 includes an electrode body part CE21, an electrode protruding part CE22, and an electrode protruding part CE23. The electrode body part CE21 is disposed facing the plurality of electrode plates CE1 and overlaps with the plurality of electrode plates CE1 in the direction perpendicular to the main surface of the base substrate. For example, the electrode body part CE21 has a block shape. In some embodiments, the electrode body part CE21 has one or more notches c1, which expose the electrode plates CE1 located underlying thereof. The notch c1 corresponds to the opening 1050 of the conductive layer 105 in FIG. 4, and may be a part of the gap between the electrode plate CE2 and the components of the transistor such as the source electrode and the drain electrode. It should be understood that the notch c1 exposing the electrode plate CE1 here means that when viewed in a plane layout, the position of the notch c1 overlaps with the electrode plate CE1, and the electrode plate CE1 at this position would not be overlaid by the electrode plate CE2. While, in fact, an insulating layer is further provided between the notch cl and the electrode plate CE1, so the notch cl would not directly expose the electrode plate CE1.

For example, the electrode body part CE21 may have a plurality of notches c1, the plurality of notches cl are disposed in one-to-one correspondence with a plurality of electrode plates CE1, and each notch cl is disposed at a position corresponding to (e.g., overlapping with) the connection region a of the corresponding electrode plate CE1. However, the present disclosure is not limited thereto. In some other examples, each notch cl can also correspond to a plurality of electrode plates CE1, and the number of the notches cl can be adjusted as needed, as long as the notch(s) c1 of the electrode plate CE2 can expose a plurality of electrode plates CE1, which is beneficial to the connection of a subsequent electrode layer and the electrode plates CE1.

In some embodiments, the electrode protruding part CE22 and the electrode protruding part CE23 protrude from the electrode body part CE21 in a direction parallel to the main surface of the base substrate (for example, direction D2). For example, the electrode protruding part CE22 protrudes from the electrode body part CE21 in the direction D2 away from the region where the source electrode and drain electrode of the transistor are located; the electrode protruding part CE23 protrudes from the electrode body part CE23 in the direction D2 towards the region where the source electrode and drain electrode of the transistor are located. The electrode protruding part CE23 may be adjacent to the source electrode and drain electrode of the transistor T (for example, a transistor at the end of a plurality of transistors) in the direction D1, and overlap with the source electrodes and drain electrodes of a plurality of transistors in the direction D1. That is, the orthographic projection of the electrode protruding part CE23 on a data signal main line SLa in the direction D1 may overlap with the orthographic projection of the source electrode and drain electrode of the transistor on the data signal main line SLa in the direction D1. However, the present disclosure is not limited thereto.

In some embodiments, the electrode protruding part CE22 and the electrode protruding part CE23 may extend beyond the edge of the electrode plate CE1 in a direction parallel to the main surface of the base substrate, that is, the electrode protruding part CE22 and the electrode protruding part CE23 do not overlap with the electrode plate CE1 in the direction perpendicular to the main surface of the base substrate.

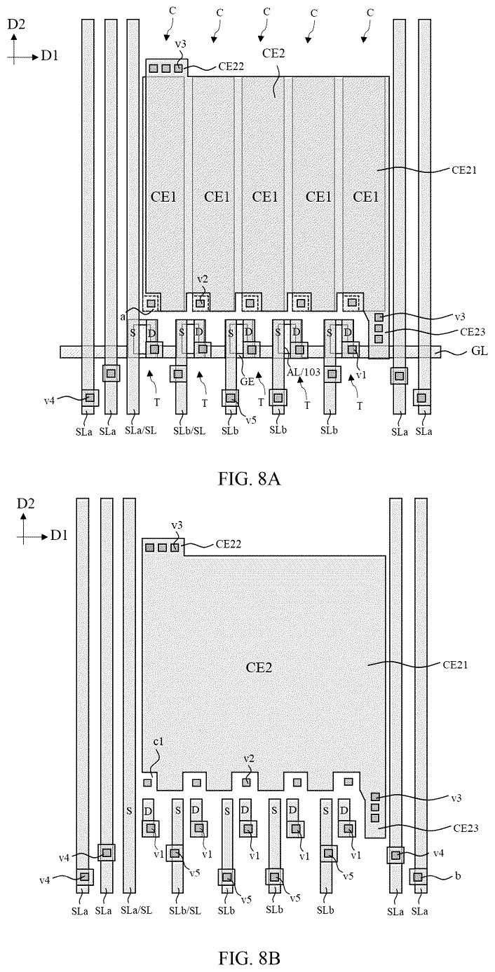

FIG. 8A illustrates a schematic plan layout of a stack of the conductive layer 101, the active layer 103, the conductive layer 105 and a plurality of via holes in an insulating layer. FIG. 8B illustrates a schematic plan layout of a stack of the conductive layer 105 and the plurality of via holes in the insulating layer.

Referring to FIGS. 4, 8A and 8B, in some embodiments, a plurality of via holes is provided in the insulating layer and used for electrical connection between different layers. For example, a plurality of via holes v1 is disposed in the insulating layer 106 to expose parts of surfaces of the drain electrodes D (for example, the connection regions thereof) of a plurality of transistors T, respectively. A plurality of via holes v2 is disposed in the insulating layers 106 and 102, for example, may located in the notches c1 of the electrode plate CE2, to expose parts of surfaces of the connection regions a of a plurality of electrode plates CE1, respectively. A plurality of via holes v3 is disposed in the insulating layer 106, to expose parts of the surface of the electrode plate CE2, for example, expose parts of the surfaces of the electrode protruding parts CE22 and CE23. In some examples, a plurality of (for example, three) via holes v3 is disposed corresponding to each electrode protruding part CE22, CE23, but the present disclosure is not limited thereto. The number of the via holes v3 can be adjusted according to product requirements.

In some embodiments, a via hole v4 and a via hole v5 are also provided in the insulating layer 106. For example, a plurality of via holes v4 respectively expose parts of surfaces of connection regions of a plurality of data signal main lines S1a; and a plurality of via holes v5 respectively expose parts of surfaces of connection regions of a plurality of data signal auxiliary lines SLb. For the data signal line SL including the data signal main line SLa and the data signal auxiliary line SLb, a via hole v4 and a via hole v5 are respectively provided corresponding to the data signal main line SLa and the data signal auxiliary line SLb, so that the subsequent transfer electrode can electrically connect the data signal main line SLa and the data signal auxiliary line SLb through the via holes v4 and v5. For the data signal line SL including only the data signal main line SLa but not including the data signal auxiliary line SLb, it is unnecessary to set a via hole corresponding to the data signal main line SLa.

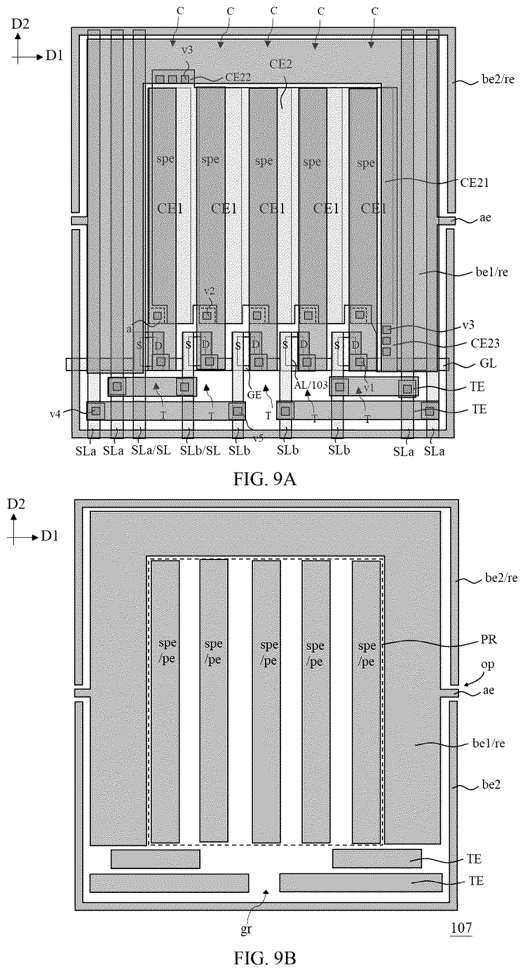

FIG. 9A illustrates a schematic plan layout of a stack of the conductive layer 101, the active layer 103, the conductive layer 105, the plurality of via holes in the insulating layer, and an electrode layer 107. FIG. 9B illustrates a plan layout of the electrode layer 107.

Referring to FIGS. 9A and 9B, the electrode layer 107 includes a pixel electrode sp, a barrier wall electrode structure, a reflective electrode and a transfer electrode TE. In some embodiments, in the pixel region PR, the pixel electrode sp includes a plurality of pixel sub-electrodes spe. For example, the plurality of pixel sub-electrodes spe include a plurality of strip-shaped electrodes, the plurality of strip-shaped electrodes are arranged in the direction D1, spaced apart from each other, and extend substantially parallel to each other in the direction D2. The barrier wall electrode structure includes a barrier wall electrode be1 and a barrier wall electrode be2; the barrier wall electrode be1 surrounds a plurality of pixel sub-electrodes spe located in the pixel region PR; the barrier wall electrode be2 is located on a side of the barrier wall electrode be1 away from the pixel region PR in a direction parallel to the main surface of the base substrate, and surrounds the barrier wall electrode be1. In some embodiments, the barrier wall electrode be1 may have an unclosed ring shape, i.e., an open ring shape. For example, the pixel region PR is in a rectangular shape, and the barrier wall electrode be1 may surround three sides of the pixel region PR, while the other one side of the pixel region PR may not be surrounded by the barrier wall electrode be1. For example, a plurality of transfer electrodes TE may be located on the side of the pixel region PR that is not surrounded by the barrier wall electrode be1, and may be located between the pixel region PR and the barrier wall electrode be2 and/or between the barrier wall electrode be1 and the barrier wall electrode be2 in the direction D2.

For example, the barrier wall electrode be2 encloses and defines a grid region gr; and the pixel electrode pe, the barrier wall electrode be1 and the transfer electrode TE are all disposed in the grid region gr surrounded by the barrier wall electrode be2. For example, each grid region gr is provided with one pixel region and a barrier wall electrode be1 surrounding the pixel region, and may include corresponding transfer electrode(s) TE.

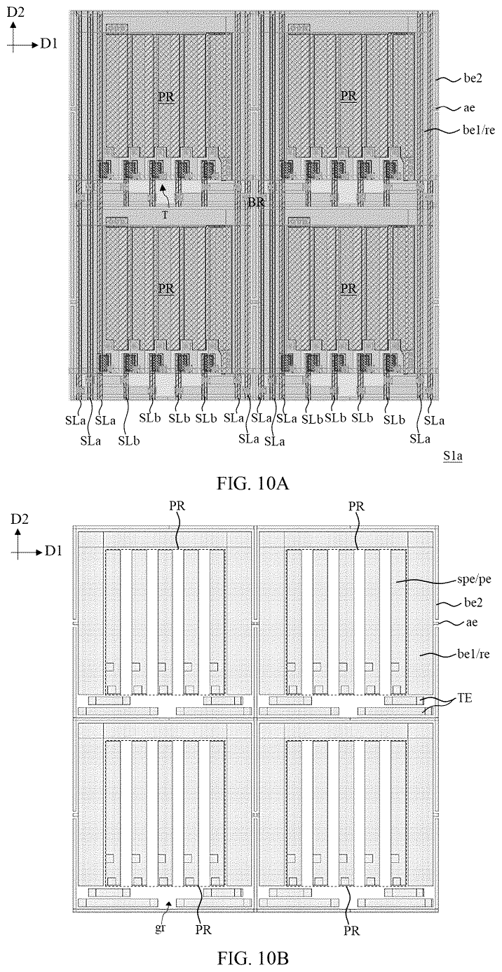

In some embodiments, the barrier wall electrode structure further includes a connection electrode ae, which is connect to the barrier wall electrode be1 and passes through the barrier wall electrode be2, for connecting the barrier wall electrode be1 with an adjacent barrier wall electrode be1 (FIGS. 10A and 10B); or the connection electrode ae located at an end may be used for connecting a voltage signal, such as a Vcom signal. For example, the barrier wall electrode be2 has an opening op, that is, a plurality of parts of the barrier wall electrode be2 are disconnected at the opening op; the connection electrode ae may extend from the edge of the barrier wall electrode be1 close to the barrier wall electrode be2, then pass through the opening op, and may further extend to the adjacent barrier wall electrode be1 (FIGS. 10A and 10B). The width of the opening op is larger than that of the connection electrode ae, so that the connection electrode ae is isolated from the barrier wall electrode be2. It should be understood that the width of the opening op and the width of the connection electrode ae refer to the width in a direction (for example, direction D2) perpendicular to the extension direction (for example, direction D1) of the connection electrode. In some embodiments, the barrier wall electrode be1 and the connection electrode ae that are connected to each other may be integrally formed.

Still referring to FIGS. 9A and 9B, each pixel sub-electrode spe is electrically connected to the drain electrode D of the corresponding transistor T through a via hole v1, and is electrically connected to the corresponding electrode plate CE1 through a via hole v2. The barrier wall electrode be1 is connected to the electrode plate CE2 through a via hole v3; in this example, the electrode plate CE2 has two electrode protruding parts CE22 and CE23, which are used as the connection regions for electrical connection with the barrier wall electrode be1, but the number of the electrode protruding parts and the number of the via holes corresponding to each electrode protruding part are not limited thereto. In some examples, a plurality of electrode protruding parts and a plurality of via holes are provided, which is beneficial to the stable connection between the barrier wall electrode be1 and the electrode plate CE21.

In some embodiments, the transfer electrodes TE may be in one-to-one correspondence with the data signal lines SL, and are electrically connected to the corresponding data signal main lines SLa and data signal auxiliary lines SLb through via holes v4 and v5, respectively, so that the data signal main line SLa and data signal auxiliary line SLb of each data signal line SL are electrically connected to each other through the corresponding transfer electrode TE.

In some embodiments, a plurality of pixel sub-electrodes spe overlaps with the electrode plate CE2 in a direction perpendicular to the main surface of the base substrate. For example, the orthographic projection of at least part of each pixel sub-electrode spe on the base substrate may be located within the orthographic projection range of the electrode plate CE2 on the base substrate.

In some embodiments, a plurality of data signal main lines SLa may be disposed in a region outside the corresponding pixel region PR, for example, disposed at one side or two opposite sides of the pixel region PR in the direction D1; the data signal main line SLa may not be disposed at the position corresponding to the gap between adjacent pixel sub-electrodes in the pixel region PR; that is, the orthographic projections of a plurality of data signal main lines SLa on the base substrate are offset from the gaps between the orthographic projections of a plurality of pixel sub-electrodes spe located in the same pixel region on the base substrate. This arrangement can avoid the signal crosstalk between adjacent pixel sub-electrodes caused by the data signal main lines when the pixel electrode in the same pixel region include a large number (for example, more than three) of pixel sub-electrodes. On the other hand, the electrode plate CE2 can be configured to connect a Vcom signal and can be multi-used as a signal shielding layer, which also facilitates shielding the signal crosstalk to the pixel sub-electrodes caused by the signal lines in the underlying conductive layer 101, because the plurality of pixel sub-electrodes spe overlap with the electrode plate CE2 (i.e., the signal shielding layer).

In some embodiments, the barrier wall electrode structure including the barrier wall electrodes be1, be2 and the connection electrode ae can also be multi-used as the reflective electrode re, thereby improving the white state display of the display device. In some embodiments, the pixel electrode sp and the barrier wall electrode structure are patterned from the same electrode material, and the pixel electrode sp can also be used as a reflective electrode, thereby further improving the white state display of the display device. In alternative embodiments, the pixel electrode sp and the barrier wall electrode structure may also be formed by different patterning processes using different electrode materials.

FIGS. 10A and 10B illustrate schematic plan layouts of a plurality of pixel regions and a barrier wall region of the array substrate Sla. It should be understood that the number of the pixel regions illustrated in FIGS. 10A and 10B is only for illustration, and the present disclosure is not limited thereto.

Referring to FIGS. 10A and 10B, in some embodiments, the display region (i.e., AA region) of the array substrate Sla includes a plurality of pixel regions PR arranged in an array and a barrier wall region BR, which surrounds the respective pixel regions and is located between adjacent pixel regions. For example, the plurality of pixel regions PR are arranged in a plurality of pixel rows along the direction D1 and arranged in a plurality of pixel columns along the direction D2. In each pixel row arranged along the direction D1 and each pixel column arranged along the direction D2, every two adjacent pixel regions are spaced apart from each other, and a barrier wall region is sandwiched therebetween. The specific structures of each pixel region PR and the barrier wall region BR surrounding the pixel region PR are the same as those described above with reference to FIGS. 5 to 9B, and will not be repeated here.

In some embodiments, a plurality of barrier wall electrodes be1 surround pixel electrodes pe in a plurality of pixel regions PR, respectively; for example, the barrier wall electrodes be1 may be disposed in one-to-one correspondence with the pixel regions PR. The plurality of barrier wall electrodes be1 may also be arranged in an array along the direction D1 and the direction D2, so as to be disposed corresponding to the plurality of pixel regions PR. In some embodiments, a plurality of barrier wall electrodes be1 located in the same row in the direction D1 (i.e., a plurality of barrier wall electrodes surrounding a plurality of pixel regions located in the same pixel row) are electrically connected to each other through connection electrodes ae. For example, one side or two opposite sides of each barrier wall electrode be1 in the direction D1 may be provided with a connection electrode ae, and the connection electrode ae is provided between every two adjacent barrier wall electrodes be1 in the direction D1, so that a plurality of barrier wall electrodes be1 located in the same row can be electrically connected with each other through the connection electrodes ae. In some embodiments, in the direction D1, the connection electrode ae located at one side, away from the pixel region PR, of one or more barrier wall electrodes at the end, may be configured to connect a voltage signal (for example, a Vcom signal). Here, the barrier wall electrode located at the end refers to the barrier wall electrode located close to the edge of the display region, and in the direction D1 there is no other pixel region provided at one side of the end barrier wall electrode.

In some embodiments, the barrier wall electrode be2 surrounds a plurality of barrier wall electrodes be1, and is spaced apart from the plurality of barrier wall electrodes be1, and is located between adjacent barrier wall electrodes be1; that is, each barrier wall electrode be1 is surrounded by the barrier wall electrode be2. For example, the barrier wall electrode be2 may be in a grid shape and define a plurality of grid regions gr; each grid region gr is provided with one pixel region PR and one barrier wall electrode be1 surrounding the pixel region PR, and may further be provided with transfer electrode(s) TE. In some embodiments, an edge portion (e.g., a portion close to the edge of the display region) of the barrier wall electrode be2 may be configured to connect a voltage signal that is different from the voltage signal to which the barrier wall electrode be1 is connected. A portion of the barrier wall electrode be2 located between every two adjacent barrier wall electrodes be1 in the direction D1 and/or a portion of the barrier wall electrode be2 located at a side of the end barrier wall electrode be1 away from the pixel region may be provided with an opening op, so that the connection electrode ae can pass through the opening for electrical connection.

In the direction D1, for two adjacent pixel regions PR, the barrier wall region between the two pixel regions PR is provided with portions of two barrier wall electrodes be1 (for example, the vertically extending portions illustrated in the figure) and a portion of the barrier wall electrode be2 (for example, the vertically extending portion illustrated in the figure) sandwiched between the two barrier wall electrodes be1; that is, the two barrier wall electrodes be1 are located on two opposite sides of the barrier wall electrode be2, the two barrier wall electrodes be1 are electrically connected to each other and can receive the same voltage signal (for example, a first voltage signal), while the barrier wall electrode be2 receives another voltage signal (for example, a second voltage signal), and the first voltage signal is different from the second voltage signal. In this way, two electric fields with opposite directions (for example, leftward and rightwards electric fields in the figure) can be generated between the barrier wall electrode be2 and the two barrier wall electrodes be1, respectively, and the two opposite electric fields form an electronic barrier wall to prevent from crosstalk of charged particles between two adjacent pixel regions. The related features and principles of the electronic barrier wall for preventing from particle crosstalk may refer to the contents described above with reference to FIG. 2A, FIG. 3C and FIG. 3D, and will not be repeated here.

In the direction D2, for two adjacent pixel regions PR, two electric fields with opposite directions (e.g., upward and downward electric fields in the figure) generated by portions of two barrier wall electrodes be1 and a portion of the barrier wall electrode be2 can also be formed between two pixel regions PR by the barrier wall electrode structure. For example, corresponding to a first pixel region (e.g., a pixel region located in a lower part of FIGS. 10A and 10B) and a second pixel region (e.g., a pixel region located in an upper part of FIGS. 10A and 10B) adjacent in the direction D2, a first electric field is generated between a portion (e.g., a horizontally extending portion along the direction D1 in the figure) of the barrier wall electrode be1 surrounding the first pixel region and an adjacent portion of the barrier wall electrode be2 (e.g., a horizontally extending portion along the direction D1 in the figure), and a second electric field is generated between a portion (for example, a part of the two vertically extending portions along the direction D2 close to the barrier wall electrode be2 in the figure) of the barrier wall electrode be1 surrounding the second pixel region and an adjacent portion of the barrier wall electrode be2 (i.e., the horizontally extending portion in the figure); the directions of the first electric field and the second electric field are opposite to each other. In some embodiments, the portion of the barrier wall electrode be1 extending in the direction D2 (i.e., the vertically extending portion) may have a relatively large size (e.g., width), for example, greater than the width of its horizontally extending portion thereof, so that the second electric field formed as described above has sufficient intensity, and the crosstalk of charged particles can be effectively blocked.

Referring to FIG. 10A, in some embodiments, a plurality of transistors T connected with a plurality of pixel sub-electrodes in each pixel region may be arranged in a row along the direction D1. In the whole display region, a plurality of transistors T in a plurality of pixel regions PR may be arranged in an array including a plurality of rows and a plurality of columns along directions D1 and D2. A plurality of transistors T located in the same row in the direction D1 (for example, their source electrodes S) may be connected to different data signal lines SL, respectively. A plurality of transistors T located in the same column in the direction D2 may be connected to the same data signal line SL. For example, a plurality of data signal main lines SLa extend along the direction D2 and are located in a region outside the pixel region PR, for example, located on opposite sides of the pixel region PR in the direction D1; each data signal main line SLa may be configured to connect a plurality of transistors T located in the same column. When the data signal line SL includes only a data signal main line SLa, the data signal main line SLa is directly connected to a plurality of transistors T (for example, their source electrodes S) in the same column. When the data signal line SL includes a data signal main line SLa and a data signal auxiliary line SLb, the plurality of transistors T connected to the data signal line SL are located in the same column and are connected to the corresponding data signal auxiliary lines SLb, respectively, and are connected to the data signal main line SLa through the corresponding data signal auxiliary lines SLb and the transfer electrodes TE. That is, the data signal line SL may include one data signal main line SLa and a plurality of data signal auxiliary lines SLb, wherein the data signal main line SLa extends along the direction D2 and may extend across a plurality of pixel regions PR to connect a plurality of transistors; while the plurality of data signal auxiliary lines SLb may be disposed in one-to-one correspondence with the plurality of transistors T. In some embodiments, the data signal auxiliary lines SLb and the transfer electrodes TE are located between adjacent signal main lines SLa in the direction D1, and between the corresponding pixel region PR and the barrier wall electrode be2 in the direction D2.

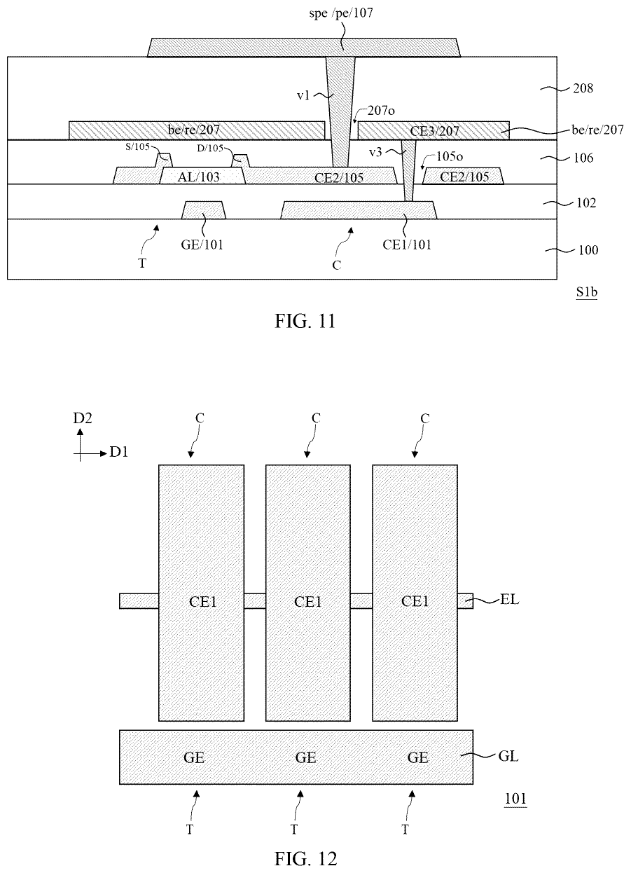

FIG. 11 illustrates a schematic cross-sectional view of an array substrate S1b according to some other embodiments of the present disclosure. The array substrate S1b is similar to the array substrate of the previous embodiment, with the difference that the layout of the components is different. For the sake of simplicity, only one pixel sub-electrode and its corresponding components such as transistor, capacitor and barrier wall electrode structure are illustrated in FIG. 11. It should be understood that other pixel sub-electrodes and other components have similar cross-sectional structures.

Referring to FIG. 11, the array substrate S1b includes a base substrate 100, a conductive layer 101, an insulating layer 102, an active layer 103, a conductive layer 105, an insulating layer 106, an electrode layer 107, and may further include an electrode layer 207 and an organic layer 208. In some embodiments, the electrode layer 107 and the electrode layer 207 may be referred to as a first electrode layer and a second electrode layer, respectively.

For example, the electrode layer 207 may be located on a side of the insulating layer 106 away from the base substrate 100, and the organic layer 208 is located on the insulating layer 106 and covers the sidewall of the electrode layer 207 and the surface of the electrode layer 207 at a side away from the insulating layer 106. The electrode layer 107 is located on a side of the organic layer 208 away from the base substrate 100. In other words, the electrode layer 207 is located on the side of the electrode layer 107 close to the base substrate 100, and between the electrode layer 107 and the conductive layer 105/insulating layer 106; and the organic layer 208 is provided between the electrode layer 207 and the electrode layer 107. In some embodiments, the organic layer 208 may be planarized; for example, the organic layer 208 may include an organic dielectric material such as spin-on glass (SOG), and may provide a flat surface for the electrode layer 107.

In some embodiments, the gate electrode GE of the transistor T and the first electrode plate CE1 of the capacitor C are disposed at the same layer of the conductive layer 101; the source/drain electrodes S/D of the transistor T and the second electrode plate CE2 of the capacitor C are disposed at the same layer of the conductive layer 105, and one of the source/drain electrodes S/D (for example, the drain electrode D) and the second electrode plate CE2 may be connected, that is, may share the same one electrode plate. In some embodiments, the barrier wall electrode structure is disposed on a side of a plurality of pixel electrodes close to the base substrate; for example, the barrier wall electrode structure be is disposed at the electrode layer 207, and can be multi-used as the reflective electrode re. The pixel electrode pe is disposed at the electrode layer 107.

In some embodiments, the pixel sub-electrode spe extends through the organic layer 208, the electrode layer 207 and the insulating layer 106, so as to be electrically connected with one of the source/drain electrodes S/D of the transistor T (for example, the drain electrode D) and the second electrode plate CE2 of the capacitor C. For example, the organic layer 208 and the insulating layer 106 are provided with a via hole v1, the electrode layer 207 is provided with an opening 2070, and the via hole v1 extends into the insulating layer 106 from the surface of the organic layer away from the base substrate and passes through the opening 2070; a portion of the via hole v1 is located in the opening 2070, has a size smaller than that of the opening 2070, and is spaced apart from the electrode layer 207. The via hole v1 exposes a part of the surface of the conductive layer 105, so that the pixel sub-electrode spe is electrically connected with the drain electrode D (or source electrode S) located at the conductive layer 105 and the second electrode plate CE2 through the via hole v1.

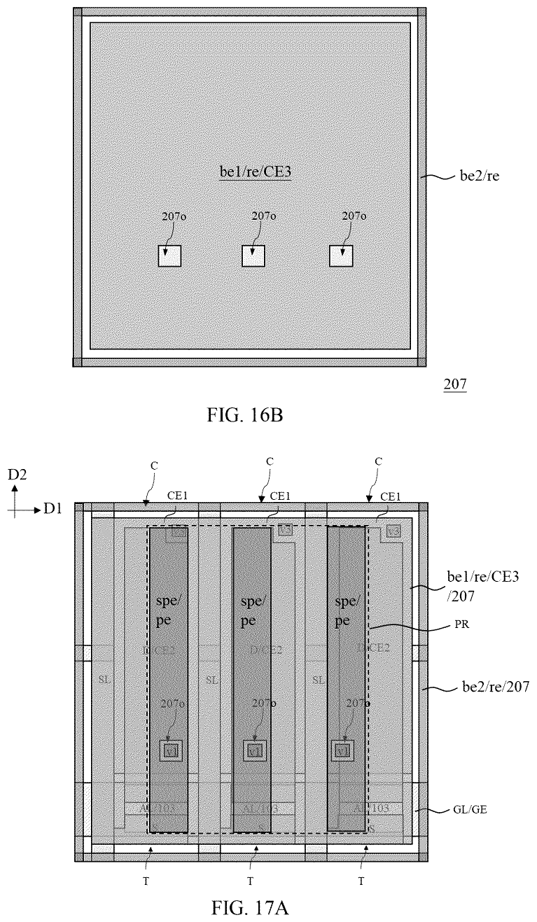

In some embodiments, a portion of the barrier wall electrode structure be extends through the insulating layer 106, the conductive layer 105 and the insulating layer 102, so as to be electrically connected with the electrode plate CE1 located at the conductive layer 101. For example, the insulating layer 106 and the insulating layer 102 are provided with a via hole v3, and the conductive layer 105 is provided with an opening 1050, which may be located in the second electrode plate CE2 or located at an edge of the second electrode plate CE2. The via hole v3 passes through the opening 1050; that is, a portion of the via hole v3 is located in the opening 1050, has a size smaller than that of the opening 1050, and is spaced apart from the conductive layer 105. The portion of the barrier wall electrode structure be (for example, the barrier wall electrode be1 illustrated in FIG. 16A) is electrically connected to the first electrode plate CE1 of the corresponding capacitor C located at the conductive layer 101 through the via hole v3. In some embodiments, the portion of the barrier wall electrode structure be and the first electrode plate CE1 of the capacitor C may be configured to receive a Vcom signal.

In some embodiments, at least part of the barrier wall electrode be may overlap with the second electrode plate CE2 in the direction perpendicular to the main surface of the base substrate 100, and may be multi-used as the third electrode plate CE3 of the capacitor C. That is, the capacitor C may include a first electrode plate CE1, a second electrode plate CE2 and a third electrode plate CE3. The first electrode plate CE1 and the third electrode plate CE3 are located on two opposite sides of the second electrode plate CE2 in the direction perpendicular to the main surface of the base substrate, and are electrically connected to each other. The capacitor C includes double-layer capacitance formed between the first electrode plate CE1 and the second electrode plate CE2, and between the second electrode plate CE2 and the third electrode plate CE3, so that the capacitance area can be increased and the capacitance of the capacitor can be improved. In some embodiments, the first electrode plate CE1 and the third electrode plate CE3 are configured to receive a Vcom signal, but the present disclosure is not limited thereto.

In this example, the pixel electrode pe and the barrier wall electrode structure be are disposed at different layers, and the barrier wall electrode structure be is multi-used as the reflective electrode re. In the direction perpendicular to the main surface of the base substrate, the pixel electrode pe may overlap with the barrier wall electrode structure be/the reflective electrode re, and the orthographic projection of the reflective electrode re on the base substrate 100 may substantially cover the entire pixel region.

FIGS. 12 to 17B illustrate schematic plan layouts of respective layers and/or a stack of multiple layers in one pixel region and a barrier wall region surrounding the pixel region in the array substrate S1b according to some embodiments of the present disclosure. In this example, the pixel electrode of each pixel region includes three pixel sub-electrodes, and the corresponding array substrate is provided with three transistors, three capacitors and three data signal lines connected to the three pixel sub-electrodes correspondingly.

FIG. 12 illustrates a plan layout of the conductive layer 101. Referring to FIG. 12, the conductive layer 101 includes a plurality of gate electrodes GE, a plurality of electrode plates CE1, a gate signal line GL and an electrode signal line EL. The plurality of gate electrodes GE correspond to a plurality of transistors T, respectively, and the plurality of electrode plates CE1 correspond to a plurality of capacitors C, respectively. The gate signal line GL is connected with a plurality of gate electrodes GE so as to be configured to apply a scanning signal to the gate electrodes GE. For example, the gate signal line GL extends in the direction D1, and is connected to a plurality of gate electrodes GE located in the same row in the direction D1. For example, a plurality of portions of the gate signal line GL may be used as a plurality of gate electrodes GE of a plurality of transistors T, respectively. A plurality of electrode plates CE1 may be arranged in the direction D1 and spaced apart from each other, and an electrode signal line EL is connected to the plurality of electrode plates CE1 so as to be configured to apply a voltage signal, such as a Vcom signal, to the electrode plates CE1. In an alternative embodiment, a plurality of electrode plates CE1 may share the same one electrode plate, and the electrode plate is, for example, in a block shape.

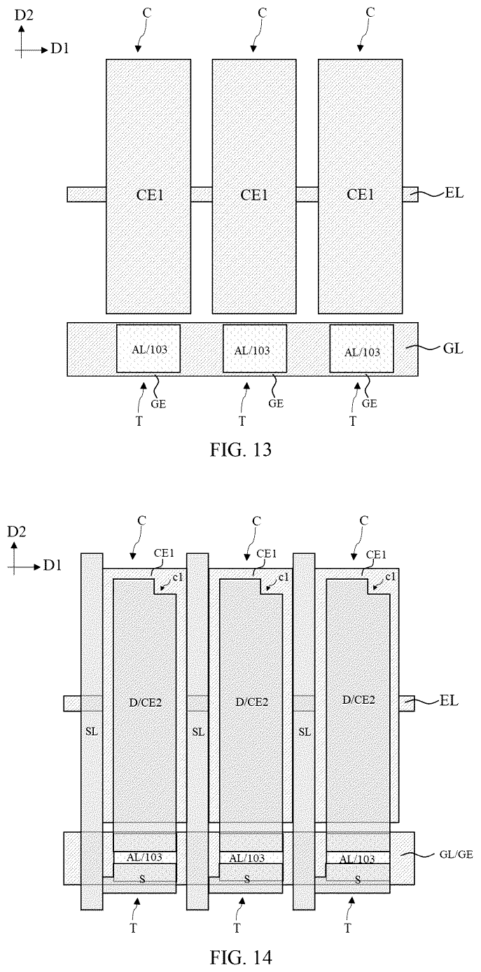

FIG. 13 illustrates a schematic plan layout of a stack of the conductive layer 101 and an active layer 103. The active layer 103 includes a plurality of active regions AL corresponding to a plurality of transistors T, respectively. The plurality of active regions AL are disposed in correspondence with the plurality of gate electrodes GE; for example, the plurality of active regions AL overlap with the plurality of gate electrodes GE in a direction perpendicular to the main surface of the base substrate.

FIG. 14 illustrates a schematic plan layout of a stack of the conductive layer 101, the active layer 103 and a conductive layer 105.

Referring to FIG. 14, the conductive layer 105 includes source electrodes S and drain electrodes D of a plurality of transistors T, electrode plates CE2 of a plurality of capacitors C, and data signal lines SL electrically connected to the plurality of transistors T, respectively. In each transistor T, the source electrode S and the drain electrode D each cover a part of the active region AL, and the other part of the active region AL is located between the source electrode S and the drain electrode D and includes a channel region of the transistor; one of the source/drain electrodes S/D (for example, the source electrode S) is electrically connected with the data signal line SL; the other one of the source/drain electrodes S/D (e.g., the drain electrode D) may share a same electrode plate with the second electrode plate CE2 of the corresponding capacitor C. The electrode plate at least partially overlaps with the first electrode plate CE1 in the direction perpendicular to the main surface of the base substrate, and extends from a position directly above the first electrode plate CE1 to a portion covering the active region AL of the corresponding transistor T.

In some embodiments, the electrode plate CE2 has a notch c1, which is located directly above the first electrode plate CE1, that is, the notch c1 overlaps with the first electrode plate CE1 in the direction perpendicular to the main surface of the base substrate. The notch c1 corresponds to the opening 1050 of the conductive layer 105 in FIG. 11; that is, the opening 1050 may be or include the notch c1. In some examples, as illustrated in FIG. 14, the notch c1 is located at the edge of the electrode plate CE2, but the present disclosure is not limited thereto. In another example, the notch c1 may also be located in the electrode plate CE2 or any other suitable position of the conductive layer 105, as long as the subsequently formed via hole can pass through the notch and expose the first electrode plate CE1.

In some embodiments, the plurality of data signal lines SL extend substantially in parallel along the direction D2 and are arranged along the direction D1, and are respectively electrically connected with the source electrodes S of a plurality of transistors T. The plurality of data signal lines SL may be located at positions laterally aside and adjacent to the corresponding transistors T, respectively. In some embodiments, when the number (equal to the number of the pixel sub-electrodes) of the transistors corresponding to the same pixel region is relatively small (e.g., smaller than or equal to 3), a part of the data signal lines SL may be disposed in the pixel region (e.g., in a region corresponding to the gap between adjacent pixel sub-electrodes in the pixel region).

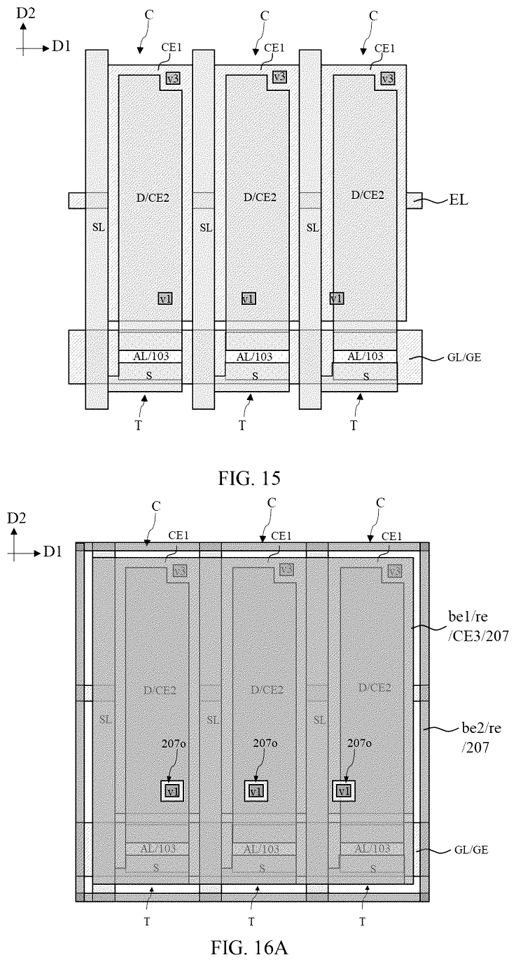

FIG. 15 illustrates a schematic plan layout of a stack of the conductive layer 101, the active layer 103, the conductive layer 105 and via holes in an insulating layer.

Referring to FIG. 15, in some embodiments, there are a plurality of via holes v1 and a plurality of via holes v3 in the insulating layer. The plurality of via holes v1 respectively expose parts of the surface of the conductive layer 105 (for example, a plurality of drain electrodes D/the second electrode plate CE2), and the plurality of via holes v3 respectively expose parts of the surfaces of a plurality of first electrode plates CE1 in the conductive layer 101. For example, the via holes v3 may be provided at positions corresponding to the notches of the electrode plates CE2, respectively.

FIG. 16A illustrates a schematic layout of a stack of the conductive layer 101, the active layer 103, the conductive layer 105, via holes in an insulating layer, and the electrode layer 207; FIG. 16B illustrates a schematic layout of the electrode layer 207.

Referring to FIGS. 16A and 16B, the electrode layer 207 includes a barrier wall electrode structure and a reflective electrode; the barrier wall electrode structure includes a barrier wall electrode be1 and a barrier wall electrode be2. The electrode layer 207 is, for example, a reflective electrode layer, that is, the barrier wall electrode structure may be multi-used as a reflective electrode. In some embodiments, the barrier wall electrode be1 may overlap with the electrode plates CE2 and CE1 in the direction perpendicular to the main surface of the base substrate; the barrier wall electrode be1 is electrically connected to a plurality of electrode plates CE1 through a plurality of via holes v3, and can be multi-used as electrode plates CE3 of the plurality of capacitors C. In some embodiments, the barrier wall electrode be1 has a block shape or a planar shape, and has a plurality of openings 2070, which overlap with a plurality of drain electrodes D/second electrode plates CE2, respectively; the plurality of openings 2070 may be disposed in one-to-one correspondence with a plurality of via holes v1, and each via hole v1 is located in the opening 2070 and has a size smaller than the opening 2070, so that the via holes v1 are spaced apart from the barrier wall electrode be1 and expose parts of surfaces of the plurality of electrode plates CE2, respectively.

In some embodiments, the barrier wall electrode be2 surrounds the barrier wall electrode be1 in the direction parallel to the main surface of the base substrate, and the barrier wall electrode be2 may be in a ring shape, such as a closed ring shape, but the present disclosure is not limited thereto.

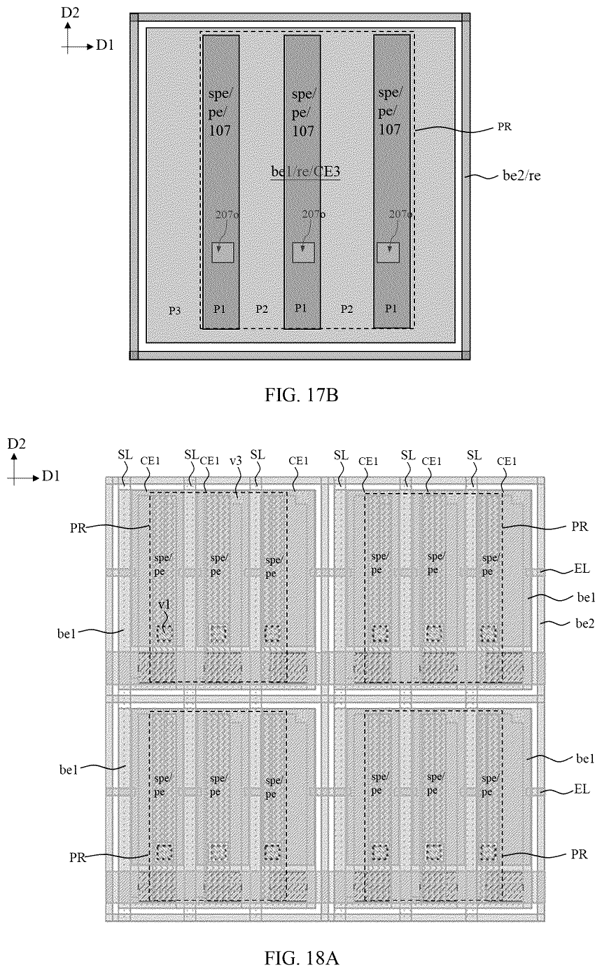

FIG. 17A illustrates a schematic layout of a stack of the conductive layer 101, the active layer 103, the conductive layer 105, via holes in an insulating layer, an electrode layer 207 and an electrode layer 107; and FIG. 17B illustrates a schematic layout of a stack of the electrode layer 207 and the electrode layer 107.

Referring to FIGS. 17A and 17B, the electrode layer 107 includes a pixel electrode pe, and the pixel electrode pe of each pixel region PR includes a plurality of pixel sub-electrodes spe, and each pixel sub-electrode spe is electrically connected to the drain electrode D of the transistor T and the second electrode plate CE2 of the capacitor C located at the conductive layer 105 through a corresponding via hole v1.

In some embodiments, the plurality of pixel sub-electrodes spe overlap with the barrier wall electrode be1 in the direction perpendicular to the main surface of the base substrate; for example, orthographic projections of a plurality of pixel sub-electrodes spe on the base substrate may be located within the orthographic projection range of the barrier wall electrode be1 on the base substrate, and the orthographic projections of the plurality of pixel sub-electrodes spe on the base substrate overlap with the orthographic projection of the opening 2070 of the barrier wall electrode be1 on the base substrate. For example, the orthographic projection of the barrier wall electrode be1 on the base substrate may cover the orthographic projection of the corresponding pixel region PR/pixel electrode pe on the base substrate; and the orthographic projection of the barrier wall electrode be1 further extends beyond the edge of the orthographic projection of the pixel region PR/pixel electrode pe, so as to surround the pixel region PR. That is, at least part of the barrier wall electrode be1 is located at a periphery of the pixel region PR, and surrounds the pixel region PR in the direction parallel to the main surface of the base substrate.

For example, each barrier wall electrode be1 includes first electrode portion(s) P1, second electrode portion(s) P2 and a third electrode portion P3; the first electrode portions P1 and the second electrode portions P2 are located in the pixel region PR, while the third electrode portion P3 is located outside the pixel region PR. The orthographic projection of the first electrode portion P1 on the base substrate and the orthographic projection of the pixel sub-electrode spe on the base substrate overlap with each other, for example, they have contours coincident with each other. The second electrode portion P2 is located between adjacent first electrode portions P1, and overlaps with the gap between adjacent pixel sub-electrodes spe in the direction perpendicular to the main surface of the base substrate; that is, the orthographic projection of the second electrode portion P2 on the base substrate overlaps with the orthographic projection of the gap between adjacent pixel sub-electrodes located in the same pixel region on the base substrate. The third electrode portion P3 surrounds the first electrode portions P1 and the second electrode portions P2, and the orthographic projection of the third electrode portion P1 on the base substrate surrounds the orthographic projection of the pixel region PR on the base substrate, for example, surrounding all sides of the orthographic projection of the pixel region PR. For example, the planar shape of the pixel region PR is a rectangular shape, and all four sides of the pixel region PR are surrounded by the third electrode portion P3. In some embodiments, the opening 2070 may be at least partially located in the corresponding first electrode portion P1.

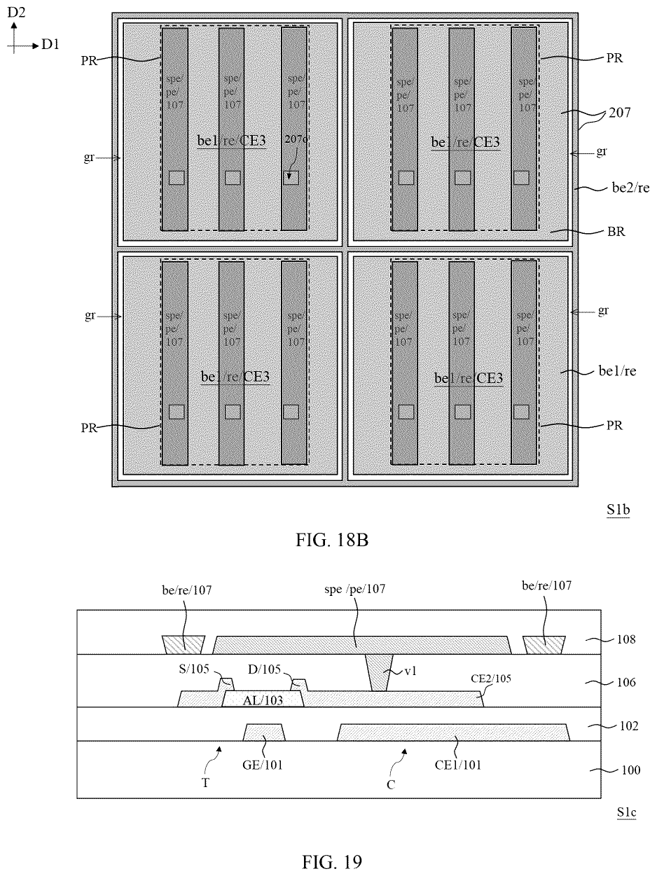

FIG. 18A illustrates a schematic plan layout of a plurality of pixel regions PR and a stack of multiple layers in barrier wall regions BR corresponding to the plurality of pixel regions PR according to some embodiments of the present disclosure. FIG. 18B illustrates a schematic layout of a plurality of pixel regions PR and a stack of electrode layers 107 and 207 in barrier wall regions BR corresponding to the plurality of pixel regions PR according to some embodiments of the present disclosure.

Referring to FIG. 18A, in some embodiments, similar to the previous embodiments, the array substrate S1b includes a plurality of pixel regions PR arranged in an array; for example, the plurality of pixel regions PR are arranged in an array including a plurality of rows and a plurality of columns along directions D1 and D2. The layout of each pixel region PR and the barrier wall region BR surrounding the pixel region is the same as that described above with reference to FIGS. 12 to 17B, and will not be repeated here.

In some embodiments, in the conductive layer 101, a plurality of electrode plates CE1 are arranged in an array including a plurality of rows and a plurality of columns along the directions D1 and D2, and a plurality of electrode lines EL extend substantially parallel to each other along the direction D1 and are arranged along the direction D2. For example, each electrode line EL may be connected to a plurality of electrode plates CE1 located in the same row. In the conductive layer 105, the source electrodes S of a plurality of transistors T may be arranged in an array including a plurality of rows and a plurality of columns along directions D1 and D2; the drain electrodes D (electrode plates CE2) of a plurality of transistors T may also be arranged in an array including a plurality of rows and a plurality of columns along directions D1 and D2. A plurality of data signal lines SL may extend substantially parallel to each other in the direction D2 and be arranged in the direction D1. For example, each data signal line SL may be connected to the source electrodes S of a plurality of transistors T located in the same column in the direction D2.

Referring to FIGS. 18A and 18B, in some embodiments, the orthographic projection of the electrode layer 107 on the base substrate overlaps with the orthographic projection of the electrode layer 207 on the base substrate, and the orthographic projection of the electrode layer 207 further covers the orthographic projection of the gap region between a plurality of pixel sub-electrodes spe in each pixel region PR on the base substrate. For example, in the electrode layer 207, a plurality of barrier wall electrodes be1 are arranged in an array along directions D1 and D2, and are respectively arranged corresponding to a plurality of pixel regions PR. The barrier wall electrode be2 surrounds a plurality of barrier wall electrodes be1 and is located between adjacent barrier wall electrodes be1. The orthographic projections of the plurality of barrier wall electrodes be1 on the base substrate respectively overlap with the orthographic projections of the plurality of pixel electrodes pe on the base substrate, and the plurality of barrier wall electrodes be1 may each have a plurality of openings 2070 respectively corresponding to the plurality of pixel sub-electrodes spe of the corresponding pixel electrode pe. Because the barrier wall electrode structure can be simultaneously used as a reflective electrode, in this example, the orthographic projection of the barrier wall electrode structure (that is, the reflective electrode) covering the pixel region can increase the coverage area of the reflective electrode, thereby further increasing the reflectivity and the contrast of the display device under white state, and hence improving the display quality of the display device.

The plurality of barrier wall electrodes be1 are connected to the electrode plates CE1 located at the conductive layer 101 through via holes v3, respectively. Because the plurality of electrode plates CE1 located in the same row are electrically connected through the electrode signal line EL, the plurality of barrier wall electrodes be1 located in the same row and electrically connected with these electrode plates CE1 are also electrically connected with each other through these electrode plates and the electrode signal line. In this example, a voltage signal, such as a Vcom signal, may be applied to the plurality of electrode plates CE1 located in the same row, and applied to the plurality of barrier wall electrodes be1 located in the same row and electrically connected to the plurality of electrode plates CE1, through the same electrode signal line EL.

Referring to FIGS. 18A and 18B, each barrier wall electrode be1 is surrounded by the barrier wall electrode be2; for example, the barrier wall electrode be2 may be in a grid shape and define a plurality of grid regions gr, and both the barrier wall electrode be1 and the pixel region PR are located in the grid region gr; for example, each grid region gr is provided with one pixel region PR and one barrier wall electrode be1. In this embodiment, because the barrier wall electrodes be1 located in the same row are electrically connected through the electrode signal line EL of the conductive layer 101, and a voltage signal can be applied to the barrier wall electrodes be1 through the electrode signal line EL, the electrode layer 207 may not be provided with a connection electrode for connecting the barrier wall electrodes be1 and/or for applying a voltage signal to the barrier wall electrodes be1, and the barrier wall electrode be2 may be correspondingly not provided with an opening for passing through the connection electrode.

For example, the barrier wall electrode be2 may be a continuous grid-like electrode and include a plurality of ring-shaped portions, and each ring-shaped portion may be in a closed ring shape to surround every side of the barrier wall electrode be1. The plurality of barrier wall electrodes be1 may be configured to receive a first voltage signal (for example, a Vcom signal), and the barrier wall electrode be2 may be configured to receive a second voltage signal different from the first voltage signal, wherein the second voltage may be greater than or smaller than the first voltage. In this way, a portion of the barrier wall electrode be2 (for example, a portion extending in the direction D2) and two barrier wall electrodes be1 located at two opposite sides of the portion of the barrier wall electrode be2 in the direction D1 are disposed between every two adjacent pixel regions PR in the direction D1; the portion of the barrier wall electrode be2 and the corresponding portions of the two barrier wall electrodes be1 generate two electric fields with opposite directions (for example, the two electric fields which are leftward and rightward in the direction D1 respectively in the figure). Moreover, a portion of the barrier wall electrode be2 (for example, a portion extending in the direction D1) and two barrier wall electrodes be1 located at two opposite sides of the portion of the barrier wall electrode be2 in the direction D2 are also disposed between every two adjacent pixel regions PR in the direction D2; the portion of the barrier wall electrode be2 and the corresponding portions of the two barrier wall electrodes be1 generate two electric fields in opposite directions (for example, the two electric fields which are upward and downward in the direction D2 respectively in the figure). The specific principle of generating the electronic barrier wall is similar to that described above with reference to FIG. 3C and FIG. 3D, and will not be described again here. Therefore, the electronic barrier wall formed by the barrier wall electrode structure including a plurality of barrier wall electrodes be1 and the barrier wall electrode be2 can effectively prevent from crosstalk of charged particles in any two adjacent pixel regions.

FIG. 19 illustrates a schematic cross-sectional view of an array substrate S1c according to some other embodiments of the present disclosure. The respective components of the array substrate S1c are similar to those of the previous embodiment, except that the layout and/or connection relationship of the respective components are slightly different.

Referring to FIG. 19, the array substrate S1c includes a base substrate 100, a conductive layer 101, an insulating layer 102, an active layer 103, a conductive layer 105, an insulating layer 106, an electrode layer 107 and a passivation layer 108. Gate electrodes GE of a plurality of transistors T and first electrode plates CE1 of a plurality of capacitors C may be located at the conductive layer 101. Source/drain electrodes S/D of the plurality of transistors T and second electrode plates CE2 of the plurality of capacitors C are located at the conductive layer 105; and one of the source/drain electrodes S/D of each transistor T (for example, the drain electrode D) and the second electrode plate CE2 of the corresponding capacitor C may be connected with each other, or may share the same one electrode plate. The pixel electrode pe, the barrier wall electrode be and the reflective electrode re are located at the electrode layer 107; and the barrier wall electrode be and the reflective electrode re may share the same one electrode. A via hole v1 may be provided in the insulating layer 106, and the pixel sub-electrode spe is connected to the drain electrode D and the second electrode plate CE2 located at the conductive layer 105 through the via hole v1.

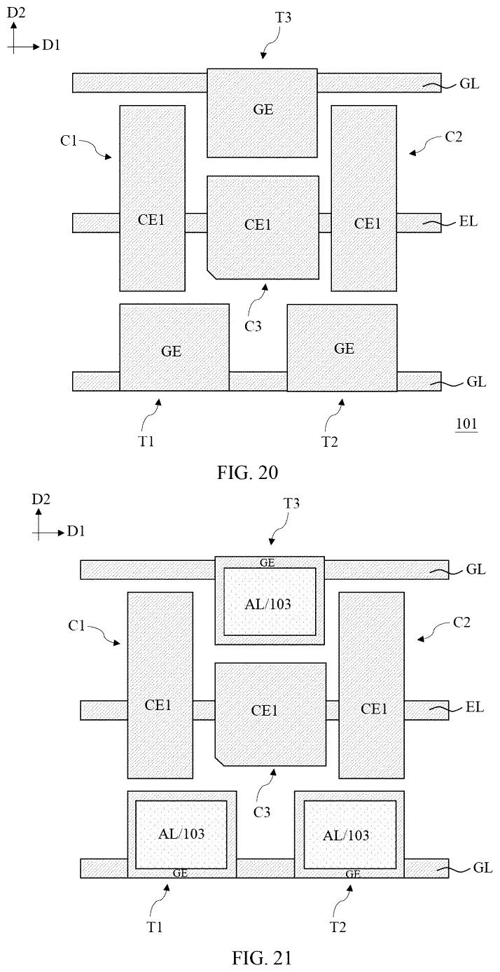

FIGS. 20 to 24B illustrate schematic plan layouts of respective layers and/or a stack of layers in one pixel region and a barrier wall region surrounding the pixel region of an array substrate S1c according to some embodiments of the present disclosure.

FIG. 20 illustrates a plan layout of a conductive layer 101 in the array substrate S1c. The conductive layer 101 includes a plurality of gate electrodes GE, a plurality of electrode plates CE1, a plurality of gate signal lines GL and an electrode signal line EL. The plurality of gate electrodes GE correspond to a plurality of transistors, respectively, and the plurality of electrode plates CE1 correspond to a plurality of capacitors, respectively. In this example, each pixel region may include three pixel sub-electrodes, and the array substrate is correspondingly provided with three transistors and three capacitors electrically connected with the three pixel sub-electrodes respectively.

In this embodiment, a plurality of transistors corresponding to the same pixel region may not be completely arranged in a row; for example, a part of the plurality of transistors are arranged in a row (for example, a first row) along the direction D1, while another part of the plurality of transistors may be arranged in another row (for example, a second row), and the transistor(s) located in the second row is/are not aligned with the transistor(s) in the first row in the direction D2. For example, at least part of the orthographic projection of the transistor located in the second row on a reference plane along the direction D1 may be located between the orthographic projections of the transistors in the first row on the reference plane. A plurality of capacitors may be located between transistors in the first row and transistors in the second row in the direction D2, the plurality of capacitors may be arranged in a row along the direction D1, and some capacitors of the plurality of capacitors may have substantially the same size, while other capacitor(s) of the plurality of capacitors may have a different size. It should be understood that the positional relationships described herein with respect to the plurality of transistors and the plurality of capacitors are substantially equivalent to the positional relationships between the corresponding components of the plurality of transistors and the plurality of capacitors in each conductor layer/active layer.

For example, the plurality of transistors and the plurality of capacitors provided corresponding to each pixel region include transistors T1, T2 and T3 and capacitors C1, C2 and C3. For example, the transistors T1 and T2 may be arranged in the same row along the direction D1, the transistor T3 is arranged in another row and located at one side of the transistors T1 and T2 in the direction D2, and the transistor T3 is not aligned with the transistor T1 or T2 in the direction D2, but is offset from the transistors T1 and T2 in the direction D1. For example, at least part of the transistor T3 may be aligned with the gap between the transistors T1 and T2 in the direction D2. The transistor T3 may partially overlap with or may not overlap with the transistor T1 and/or transistor T2 in the direction D2. In other words, at least part of the orthographic projection of the transistor T3 on a reference plane along the direction D1 is located between the orthographic projections of the transistors T1 and T2 on the reference plane, and the orthographic projection of the transistor T3 may partially overlap with or may not overlap with the orthographic projection(s) of the transistor T1 and/or the transistor T2.

The capacitors C1, C3 and C2 may be arranged in sequence along the direction D1, and may be arranged, in the direction D2, between the transistor row where the transistors T1 and T2 are located and the transistor row where the transistor T3 is located. For example, the capacitors C1 and C2 may at least partially overlap with the transistors T1 and T2 in the direction D2, respectively; the capacitor C3 may overlap with the transistor T3 in the direction D2; at least part of the capacitor C3 may overlap with the gap between the transistors T1 and T2, and may or may not partially overlap with the transistors T1 and/or T2, in the direction D2. In some embodiments, the capacitors C1 and C2 may have substantially the same shape and/or size, and the shapes and/or sizes of the capacitors C1 and C2 may be different from those of the capacitor C3.

In the conductive layer 101, the arrangement of the gate electrodes GE of the plurality of transistors T1-T3 and the electrode plates CE1 of the plurality of capacitors C is basically the same as those described above with respect to the transistors and capacitors, and the details are not repeated here.

In some embodiments, the gate electrodes GE of a plurality of transistors located in the same row are connected to the same gate signal line GL. For example, the gate electrodes GE of the transistors T1 and T2 are connected to the same gate signal line GL, while the gate electrode GE of the transistor T3 is connected to another gate signal line GL. A plurality of gate signal lines GL may extend substantially parallel to each other in the direction D1 and be arranged in the direction D2.

The electrode plates of a plurality of capacitors located in the same row may be connected to the same electrode signal line. For example, the electrode plates CE1 of the capacitors C1, C2 and C3 may be connected to the same electrode signal line EL; the electrode signal line EL may extend in the direction D1 and may be arranged between two adjacent gate signal lines GL in the direction D2.

FIG. 21 illustrates a schematic layout of a stack of a conductive layer 101 and an active layer 103. The active layer 103 includes a plurality of active regions AL corresponding to a plurality of transistors, respectively. Each active region AL is disposed in correspondence with and overlaps with a corresponding gate electrode GE in the direction perpendicular to the main surface of the base substrate. For example, the orthographic projection of the active region AL on the base substrate may be located within the orthographic projection range of the corresponding gate electrode GE on the base substrate.

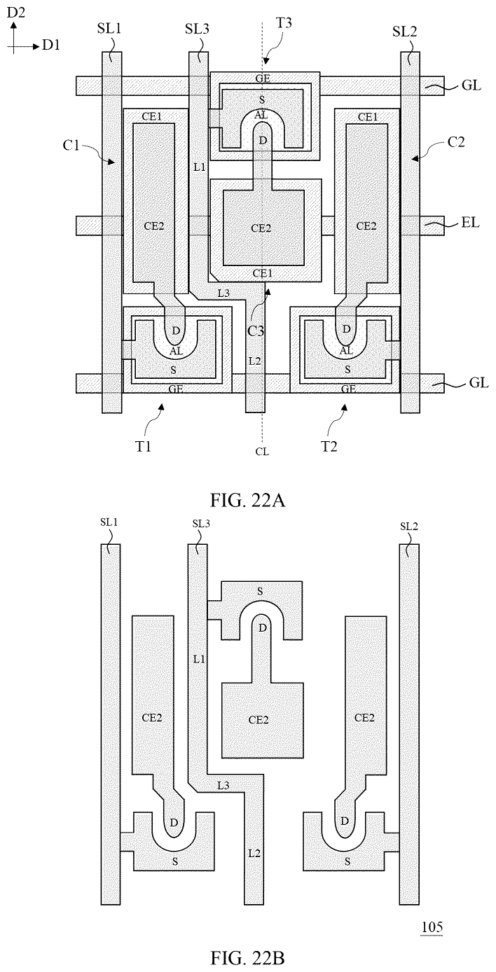

FIG. 22A illustrates a schematic plan layout of a stack of the conductive layer 101, the active layer 103 and the conductive layer 105. FIG. 22B illustrates a schematic plan layout of the conductive layer 105.

Referring to FIGS. 22A and 22B, the conductive layer 105 includes source/drain electrodes S/D of the plurality of transistors, electrode plates CE2 of the plurality of capacitors, and a plurality of data signal lines SL1, SL2 and SL3. One of the source/drain electrodes S/D (e.g., the drain electrode D) of each transistor may be electrically connected with the second electrode plate CE2 of the corresponding capacitor; in other words, each drain electrode D may share the same electrode plate with the corresponding second electrode plate CE2, wherein a part of the electrode plate is used as the second electrode plate CE2 of the capacitor, and another part of the electrode plate is used as the drain electrode of the transistor. The other one of the source/drain electrodes S/D (for example, the source electrode S) is electrically connected with the corresponding data signal line; for example, the source electrodes S of the transistors T1, T2 and T3 are connected to data signal lines SL1, SL2 and SL3, respectively. The source electrode S and the drain electrode D each cover a part of the active region AL and are disposed facing each other. For example, the source electrode S may have a U-shaped groove, and at least part of the drain electrode D may be located in the U-shaped groove and surrounded by the source electrode S in a direction parallel to the main surface of the base substrate, but the present disclosure is not limited thereto. Each electrode plate CE2 is disposed facing the corresponding electrode plate CE1, that is, each electrode plate CE2 and the corresponding electrode plate CE1 overlap each other in the direction perpendicular to the main surface of the base substrate. The arrangement of the source/drain electrodes S/D of the plurality of transistors and the electrode plates CE2 of the plurality of capacitors are correspondingly substantially the same as the arrangement of the plurality of transistors and the plurality of capacitors described above.

In some embodiments, the U-shaped grooves of the source electrodes S of the transistors located in the same row have the same opening directions, while the U-shaped grooves of the source electrodes S of the transistors located in adjacent rows have different opening directions. For example, as illustrated in FIGS. 22A and 22B, the opening directions of the U-shaped grooves of the source electrodes S of the transistors T1 and T2 are both upward, while the opening direction of the U-shaped groove of the source electrode S of the transistor T3 is downward. It should be understood that, the types of transistors illustrated in various embodiments are for illustration, and the present disclosure is not limited thereto. Any suitable type of transistor (for example, U-type, T-type or other types) can be selected based on product requirements.

In some embodiments, for the same pixel region, data signal lines SL1 and SL2 connected with two transistors T1 and T2 located at the ends of a plurality of transistors T1-T3 may extend substantially parallel to each other along the direction D2, and the data signal lines SL1 and SL2 may each be substantially strip-shaped and extending in a single direction, that is, in a linear shape; while the data signal line SL3 connected to the transistor T3 located in the middle position may include portions extending in a plurality of directions, that is, the data signal line SL3 may be in a zigzag shape. Here, the two transistors located at the ends refer to the transistors (e.g., transistors T1 and T2) located at two ends (e.g., close to the edge of the pixel region) in the row direction (e.g., direction D1) among a plurality of transistors corresponding to the same pixel region, while the transistor at the middle position refers to other transistor(s) (e.g., transistor T3) located between the end transistors (and relatively away from the edge of the pixel region in the direction D1, for example) among a plurality of transistors corresponding to the same pixel region. It should be understood that, the position of the transistor T3 being between the end transistors T1 and T2 here does not mean that the transistor T3 is right in the middle between the transistors T1 and T2, but that the orthographic projection of the transistor T3 on a reference plane along the direction D1 is between the orthographic projections of the transistors T1 and T2 on the reference plane.

For example, the data signal line SL3 may include a first body portion L1, a second body portion L2, and a connecting portion L3. The first body portion L1 and the second body portion L2 may extend in the direction D2 and be offset from each other in the direction D1, and the transition portion L3 is located between the first body portion L1 and the second body portion L2 so that the first body portion L1 and the second body portion L2 may be electrically connected to each other through the connecting portion L3. For example, the connecting portion L3 may extend in another direction (e.g., direction D1) intersecting with the direction D2. For example, the first body portion L1 may be located between the capacitors C1 and C3, and between the capacitor C1 and the transistor T3, in the direction D1; the second body portion L2 may be located between the transistors T1 and T2 in the direction D1; the connecting portion L3 may be located between the capacitor C3 and the transistor T1 in the direction D2. However, the present disclosure is not limited thereto. In an alternative embodiment, the data signal line SL3 may also be disposed at a position symmetrical to the position illustrated in FIG. 22A; for example, the first body portion L1 may be located between the capacitors C2 and C3, and between the capacitor C2 and the transistor T3, in the direction D1; the second body portion L2 may be located between the transistors T1 and T2 in the direction D1; the connecting portion L3 may be located between the capacitor C3 and the transistor T2 in the direction D2.

In some embodiments, the gate electrodes GE, the source/drain electrodes S/D and the active layers AL of the transistors T1-T3, the electrode plates CE1-CE2 of the capacitors C1-C3, and the data signal line SL2 connecting the transistor T2 at the middle position may all be disposed, in the direction D1, between the data signal lines SL1 and SL2 connecting the end transistors. This arrangement facilitates to reducing the area of the pixel driving circuit disposed corresponding to the pixel region, and minimizing the pitch of adjacent pixel regions, thereby increasing the pixel density and hence improving the display resolution.

In some embodiments, the drain electrode D of the transistor T1 and the second electrode plate CE2 of the capacitor C1 share the same electrode plate (e.g., a first electrode plate); the drain electrode D of the transistor T2 and the second electrode plate CE2 of the capacitor C2 share the same electrode plate (e.g., a second electrode plate). For example, the first electrode plate and the second electrode plate may be disposed symmetrically to each other, for example, with respect to the center line CL. The center line CL extends in the direction D2, for example, and passes through the center of the electrode plate CE1 or CE2 of the capacitor C1, or passes through the center of the gate electrode GE or the active region AL of the transistor T3. For example, the gate electrode GE, the active region AL and/or the source/drain electrodes S/D of the transistor T3, and the electrode plates CE1 and/or CE2 of the capacitor C3, may each be symmetrically disposed with respect to the center line CL. For example, the corresponding components of the respective layers in the transistors T1 and T2 may be disposed symmetrically with each other with respect to the center line CL; the corresponding components of the respective layers in the capacitors C1 and C2 may be disposed symmetrically with each other with respect to the center line CL. In some embodiments, the above arrangement of the transistors and the capacitors facilitates to minimizing the pitch of adjacent pixel regions, thereby increasing the pixel density and hence improving the display resolution.

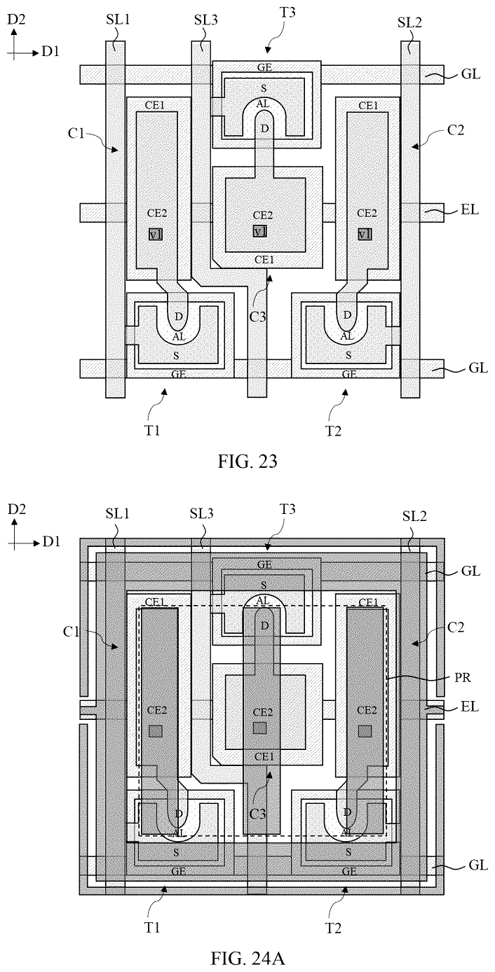

FIG. 23 illustrates a schematic layout view of a stack of the conductive layer 101, the active layer 103, the conductive layer 105, and via holes in an insulating layer.

Referring to FIG. 23, a plurality of via holes v1 are disposed in the insulating layer. The plurality of via holes v1 may respectively expose portions of the surfaces of a plurality of electrode plates each shared by an electrode plate CE2 and a drain electrode D. For example, the via hole v1 may expose a portion of the surface of the electrode plate CE2, and is used to realize the electrical connection between the overlying pixel sub-electrode and each of the electrode plate CE2 and the drain electrode D.

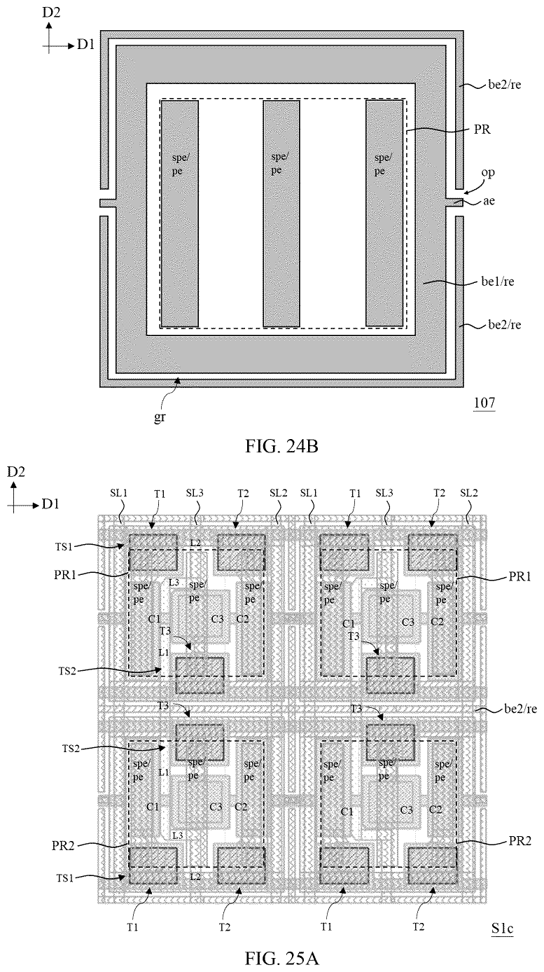

FIG. 24A illustrates a schematic plan layout of a stack of the conductive layer 101, the active layer 103, the conductive layer 105, via holes in the insulating layer and an electrode layer 107; FIG. 24B illustrates a schematic plan layout of the electrode layer 107.

Referring to FIGS. 24A and 24B, in some embodiments, the pixel electrode pe, the barrier wall electrode structure and the reflective electrode structure may be disposed at the same layer of the electrode layer 107. In each pixel region PR, the pixel electrode pe may include a plurality (e.g., 3 or less) of pixel sub-electrodes spe; the plurality of pixel sub-electrodes spe may extend substantially parallel to each other in the direction D2 and be arranged in the direction D1. For example, the plurality of pixel sub-electrodes spe may be strip electrodes. The barrier wall electrode structure may include a barrier wall electrode be1, a barrier wall electrode be2 and a connection electrode ae. The barrier wall electrode be1 may be disposed in one-to-one correspondence with the pixel region PR, and located between the corresponding pixel region PR and the barrier wall electrode be2. For example, each barrier wall electrode be1 surrounds the pixel electrode pe in the pixel region PR in a direction parallel to the main surface of the base substrate; the barrier wall electrode be1 may have a ring shape, for example, a closed ring shape, and a plurality of pixel sub-electrodes spe may be located in an area surrounded by the inner sidewall of the corresponding barrier wall electrode be1 (i.e., the sidewall away from the barrier wall electrode be2). The barrier wall electrode be2 is located at the side of the barrier wall electrode be1 away from its corresponding pixel region PR, and surrounds the barrier wall electrode be1 in the direction parallel to the main surface of the base substrate. For example, each barrier wall electrode be1 is surrounded by a barrier wall electrode be2.

In some embodiments, a portion of the barrier wall electrode be2 corresponding to each barrier wall electrode be1 may be ring-shaped. For example, the barrier wall electrode be2 defines a grid region gr, and each grid region gr is provided with one pixel region and a barrier wall electrode be1 surrounding the pixel region.

In some embodiments, a portion of the barrier wall electrode be2 corresponding to each barrier wall electrode be1 may be open ring-shaped; for example, the barrier wall electrode be2 may have a plurality of openings op, and the connection electrode ae may be located at one or two sides of the barrier wall electrode be1 in the direction D1, and the connection electrode ae passes through the opening op of the barrier wall electrode be2 for connecting the barrier wall electrodes be1 located in the same row in the direction D1 or for connecting a voltage signal (for example, a Vcom signal). Related features of the barrier wall electrode be2 and the connection electrode ae are similar to those described above with reference to FIGS. 9A and 9B, and will not be repeated here.

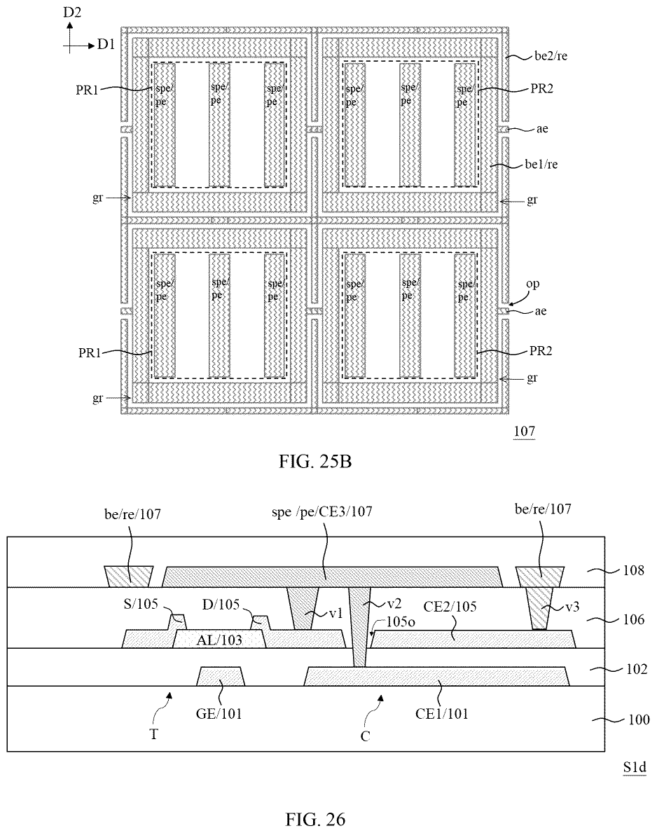

FIG. 25A illustrates a schematic layout view of respective layers and/or a stack of layers in a plurality of pixel regions PR and a barrier wall region BR corresponding to the plurality of pixel regions PR, of an array substrate S1c according to some embodiments of the present disclosure. FIG. 25B illustrates a schematic layout view of an electrode layer 107 in a plurality of pixel regions PR and in a barrier wall region BR corresponding to the plurality of pixel regions PR, of an array substrate S1c according to some embodiments of the present disclosure. The layout of respective layers in each pixel region PR and its corresponding barrier wall region is the same as or similar to those described above with reference to FIGS. 20 to 24B.

Referring to FIG. 25A, in some embodiments, the display region of the array substrate S1c includes a plurality of pixel regions, and the plurality of pixel regions may be arranged in an array including a plurality of rows and a plurality of columns, for example, along directions D1 and D2. For example, the plurality of pixel regions include a plurality of pixel regions PR1 and a plurality of pixel regions PR2, and the plurality of pixel regions PR1 are arranged in a row along the direction D1, such as a first pixel row; the plurality of pixel regions PR2 are arranged in a row along the direction D1, for example, a second pixel row; the plurality of pixel regions PR1 and PR2 may be arranged in a column along the direction D2. In some embodiments, the first pixel row and the second pixel row are alternately disposed with each other in the direction D2.

Among the plurality of pixel regions PR1 and PR2, the layout of each pixel region PR2 and its surrounding barrier wall region is the same as that described above with reference to FIGS. 20 to 24B, and the layout of each pixel region PR1 and its surrounding barrier wall region is substantially the same as that of the pixel region PR2, except that the orientations of the components in the pixel region PR1 are different; for example, the components in the pixel region PR1 are inverted with respect to those in the pixel region PR2 in the direction D2. The relative positional relationships of the components in the pixel region PR1 are substantially the same as those described with respect to the pixel region PR2.

In some embodiments, the overall structures of pixel regions PR1 and PR2 that are located in the first and second pixel rows adjacent to each other and located in the same column in the direction D2 are inverted relative to each other in the direction D2. For example, the pixel regions PR1 and PR2 may be disposed symmetrically with respect to each other, for example, disposed symmetrically with respect to the barrier wall electrode be2 located therebetween. The relatively inverted arrangement of the first and second pixel rows adjacent to each other can be beneficial to the arrangement of data signal lines, and be beneficial to minimizing the pitch of adjacent pixel regions, thereby increasing the pixel density and hence improving the display resolution.

For example, each pixel region includes transistors T1, T2 and T3; a plurality of transistors T1 and T2 corresponding to the same pixel region row are arranged in a row along the direction D1, for example, in a first transistor row TS1, and the transistors T1 and T2 are alternately arranged in the first transistor row; a plurality of transistors T3 corresponding to the same pixel region row are arranged in a row along the direction D1, for example, in a second transistor row TS2. A plurality of transistors in a plurality of first transistor rows are aligned in the direction D2 and arranged in columns; for example, a plurality of transistors T1 are arranged in a column (for example, a first transistor column) in the direction D2, and a plurality of transistors T2 are arranged in a column (for example, a second transistor column) in the direction D2. A plurality of transistors T3 in a plurality of second transistor rows are aligned in the direction D2 and arranged in a column, such as a third transistor column. The third transistor column is arranged between the adjacent first and second transistor columns in the direction D1. It should be understood that the number of the pixel regions illustrated in the figure is merely for illustration, and the present disclosure is not limited thereto. For example, more pixel regions can be disposed in each pixel row and each pixel column; for example, a second pixel row PR2 may be further arranged above the first pixel row PR1 in the figure, and a first pixel row PR1 may be further arranged below the second pixel row PR2 in the figure.

In the pixel regions PR1 and PR2 that are located in the same pixel column and adjacent pixel rows, a plurality of transistors T1-T3 in the pixel region PR1 and a plurality of transistors T1-T3 in the pixel region PR2 are symmetrically disposed. For example, there is a first distance between the transistor T1 in the pixel region PR1 and the transistor T1 in the pixel region PR2; there is a second distance between the transistor T2 in the pixel region PR1 and the transistor T2 in the pixel region PR2; there is a third distance between the transistor T3 in the pixel region PR1 and the transistor T3 in the pixel region PR2; the first distance and the second distance are substantially the same as each other, and the third distance is different from the first distance and the second distance. The first distance, the second distance and the third distance are all distances in the direction D2.

In some embodiments, in the adjacent first pixel row and second pixel row, transistor rows of the same type (for example, the first transistor rows or the second transistor rows) are adjacent to each other and are disposed at two opposite sides of the barrier wall region in the direction D2, and these adjacent transistor rows may be referred to as an adjacent transistor group; while transistor rows of another type (for example, the second transistor rows or the first transistor rows) are disposed at two opposite sides of the adjacent transistor group in the direction D2. For example, a first transistor row and a first transistor row are adjacent to each other and constitute a first adjacent transistor group, and two second transistor rows are disposed on two opposite sides of the first adjacent transistor group in the direction D2; alternatively, a second transistor row and a second transistor row are adjacent to each other and constitute a second adjacent transistor group, and two first transistor rows are disposed on two opposite sides of the second adjacent transistor group in the direction D2.

For example, in the adjacent first pixel row and second pixel row illustrated in FIG. 25A, two second transistor rows TS2 are adjacent to each other in the direction D2, and are disposed on two opposite sides of the barrier wall region (for example, the barrier wall electrode be2) and constitute a second adjacent transistor group; two first transistor rows TS1 are disposed on two opposite sides, in the direction D2, of the second adjacent transistor group constituted by the two transistor rows TS2.

In some adjacent first pixel rows and second pixel rows, two second transistor rows TS2 are adjacent to each other and constitute a second adjacent transistor group; in some other adjacent first pixel rows and second pixel rows (for example, the first pixel row in the figure and a second pixel row (not illustrated) above it; or the second pixel row in the figure and a first pixel row (not illustrated) below it), two first transistor rows TS1 are adjacent to each other and constitute a first adjacent transistor group. For example, in the direction D2, the first adjacent transistor group and the second adjacent transistor group may be alternately arranged.

Referring to FIG. 25A, in some embodiments, a plurality of data signal lines SL1 and SL2 extend substantially parallel to each other in the direction D2, and each data signal line SL1 may be connected to the source electrodes S of a plurality of transistors T1 arranged in the same column in the direction D2; each data signal line SL2 may be connected to the source electrodes S of a plurality of transistors T2 arranged in the same column in the direction D2; each data signal line SL3 may be connected to the source electrodes S of a plurality of transistors T3 arranged in the same column in the direction D2; the data signal line SL3 may have a symmetrical structure; for example, a portion of the data signal line SL3 corresponding to the adjacent pixel regions PR1 and PR2 may be symmetrical with respect to the barrier wall electrode be2 between the adjacent pixel regions. For example, a portion of the data signal line SL3 corresponding to each pixel region includes a first body portion L1, a second body portion L2 and a connecting portion L3. Moreover, the first body portion L1 of a portion of the data signal line SL3 corresponding to the pixel region PR1 is connected with the first body portion L1 of a portion of the data signal line SL3 corresponding to the pixel region PR2; and the second body portion L2 of a portion of the data signal line SL3 corresponding to the pixel region PR1 is connected with the second body portion L2 of a portion of the data signal line SL3 corresponding to the pixel region PR2.

Referring to FIG. 25B, in the array substrate S1c, the pixel electrodes pe, the barrier wall electrode structures and the reflective electrodes of a plurality of pixel regions may all be disposed at the same layer of the electrode layer 107. The pixel electrode pe in each pixel region may include three pixel sub-electrodes spe. The barrier wall electrode structure may include a plurality of barrier wall electrodes be1, a barrier wall electrode be2 and a connection electrode ae. The plurality of barrier wall electrodes be1 surround the pixel electrodes pe in a plurality of pixel regions PR, respectively, and each barrier wall electrode be1 is surrounded by the barrier wall electrode be2. That is, the barrier wall electrode be2 surrounds a plurality of barrier wall electrodes be1 and is disposed between adjacent barrier wall electrodes be1.

The plurality of barrier wall electrodes be1, the barrier wall electrode be2 and the connection electrode ae of the barrier wall electrode structure may all be disposed outside the pixel region, that is, the orthographic projection of the barrier wall electrode structure on the base substrate may not overlap with the orthographic projections of a plurality of pixel sub-electrodes on the base substrate, and may not overlap with the orthographic projection of the gap between adjacent pixel sub-electrodes in the same pixel region on the base substrate.

A plurality of barrier wall electrodes be1 are disposed in an array along directions D1 and D2; similar to the embodiments illustrated in FIGS. 9A and 9B, the plurality of barrier wall electrodes be1 corresponding to a plurality of pixel regions of the same pixel row are electrically connected to each other through a connection electrode ae, and a voltage signal, such as a Vcom signal, can be applied to the barrier wall electrodes be1 of this row through the connection electrode ae located at a side of the end barrier wall electrode be1 in the direction D1. In some embodiments, barrier wall electrodes be1 located in different rows, that is, all barrier wall electrodes be1 may be configured to receive the same voltage signal (a first voltage signal), such as a Vcom signal.

Similar to the previous embodiments, the barrier wall electrode be2 may be in a grid shape and define a plurality of grid regions gr, and each grid region gr is provided with one pixel region and the barrier wall electrode be1 surrounding the pixel region. In this example, the barrier wall electrode be2 has a plurality of openings op, that is, the barrier wall electrode be2 has a plurality of portions disconnected from each other, and the plurality of portions of the barrier wall electrode be2 are configured to receive the same voltage signal (a second voltage signal). The first voltage signal and the second voltage signal are different, so that an electric field in a predetermined direction is generated between adjacent barrier wall electrodes be1 and be2.

Between every two pixel regions PR1 or PR2 that are adjacent in the direction D1, the barrier wall electrode be2 and the barrier wall electrodes be1 located at two opposite sides of the barrier wall electrode be2 are configured to form two electric fields with opposite directions (for example, the leftward and rightward directions in the figure). Between every two pixel regions PR1 and PR2 that are adjacent in the direction D2, the barrier wall electrode be2 and the barrier wall electrodes be1 located at two opposite sides of the barrier wall electrode be2 are configured to form two electric fields with opposite directions (for example, upward and downward directions in the figure). In this embodiment, the way in which the barrier wall electrode be1 and the barrier wall electrode be2 form an electronic barrier wall is similar to that described in the previous embodiment with respect to FIGS. 18A and 18B, and will not be repeated here.

FIG. 26 illustrates a schematic cross-sectional view of an array substrate S1d according to some other embodiments of the present disclosure. The array substrate S1d includes a base substrate 100, a conductive layer 101, an insulating layer 102, an active layer 103, a conductive layer 105, an insulating layer 106, an electrode layer 107 and a passivation layer 108. Gate electrodes GE of a plurality of transistors T and first electrode plates CE1 of a plurality of capacitors C may be located at the conductive layer 101. Source/drain electrodes S/D of a plurality of transistors T and second electrode plates CE2 of a plurality of capacitors C are located at the conductive layer 105. The pixel electrode pe, the barrier wall electrode structure be and the reflective electrode re may be located at the electrode layer 107; and the barrier wall electrode structure be and the reflective electrode re may share the same one electrode. A via hole v1 may be provided in the insulating layer 106, and the pixel sub-electrode spe is connected to one of the source/drain electrodes S/D (e.g., the drain electrode D) located in the corresponding transistor T and the second electrode plate CE2 of the corresponding capacitor C through the via hole v1. A via hole v2 is provided in the insulating layers 106 and 102, and the pixel sub-electrode spe is connected to the electrode plate CE1 located in the corresponding capacitor C through the via hole v2; a via hole v3 is also provided in the insulating layer 106, and a portion of the barrier wall electrode structure (for example, the barrier wall electrode be1) is electrically connected to the electrode plate CE2 located at the conductive layer 105 through the via hole v3. The structural/positional relationship of the respective components in the cross-sectional structure of the array substrate S1d is substantially the same as that of the array substrate Sla illustrated in FIG. 4, and will not be repeated here. The array substrate S1d is different from the array substrate Sla in that the plan layout of the respective components may be different.

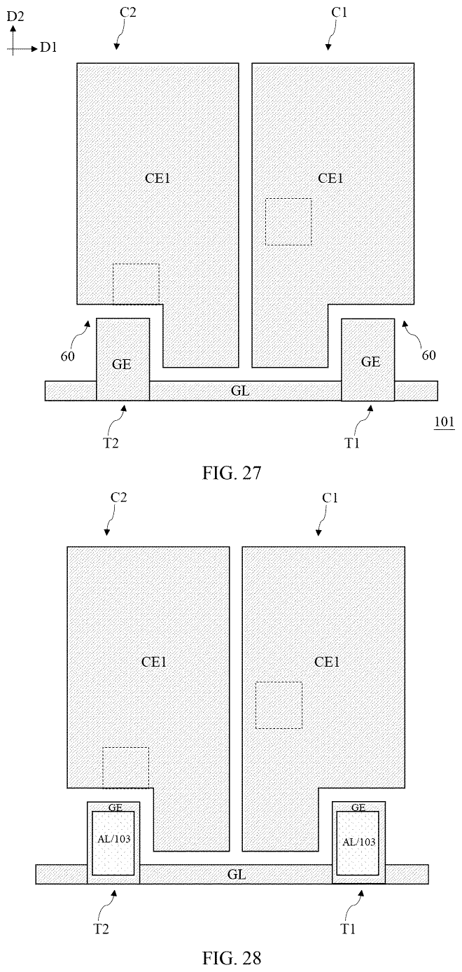

FIG. 27 to FIG. 31B illustrate schematic plan layouts of respective layers and/or a stack of multiple layers in one pixel region and a barrier wall region surrounding the pixel region in an array substrate S1d. In some embodiments, the pixel electrode in each pixel region of the array substrate S1d includes two pixel sub-electrodes, and the array substrate is provided with two transistors, two capacitors and two data signal lines correspondingly connected to the two pixel sub-electrodes.

FIG. 27 illustrates a plan layout of a conductive layer 101. The conductive layer 101 includes a plurality of gate electrodes GE, a plurality of electrode plates CE1, and a gate signal line GL. The plurality of gate electrodes GE correspond to a plurality of transistors T1 and T2 respectively, and the plurality of electrode plates CE1 correspond to a plurality of capacitors C1 and C2 respectively. The plurality of gate electrodes GE may be disposed in a row along the direction D1, and the gate signal line GL connects a plurality of gate electrodes GE located in the same row and is configured to apply a gate signal to the plurality of gate electrodes GE. In some embodiments, two electrode plates CE1 corresponding to the same one pixel region may be disposed along the direction D1 and may be symmetrically disposed with each other; The electrode plate CE1 may have a recessed area 60, and a portion of the gate electrode GE may be located in the recessed area 60 and spaced apart from the electrode plate CE1. In some embodiments, the regions (i.e., connection regions) of the plurality of electrode plates CE1 configured for being connected with the pixel sub-electrodes are illustrated in the figure with dashed boxes, and the connection regions of two electrode plates CE1 corresponding to the same pixel region may not be aligned in the direction D1.

FIG. 28 illustrates a schematic layout of a stack of the conductive layer 101 and an active layer 103. Similar to the previous embodiment, the active layer 103 includes a plurality of active regions AL corresponding to a plurality of transistors T1 and T2, respectively. Each active region AL is disposed in correspondence with a corresponding gate electrode GE; for example, the active region AL overlaps with the gate electrode GE in the direction perpendicular to the main surface of the base substrate, and the orthographic projection of the active region AL on the main surface of the base substrate may be located within the orthographic projection range of the corresponding gate electrode GE on the main surface of the base substrate.

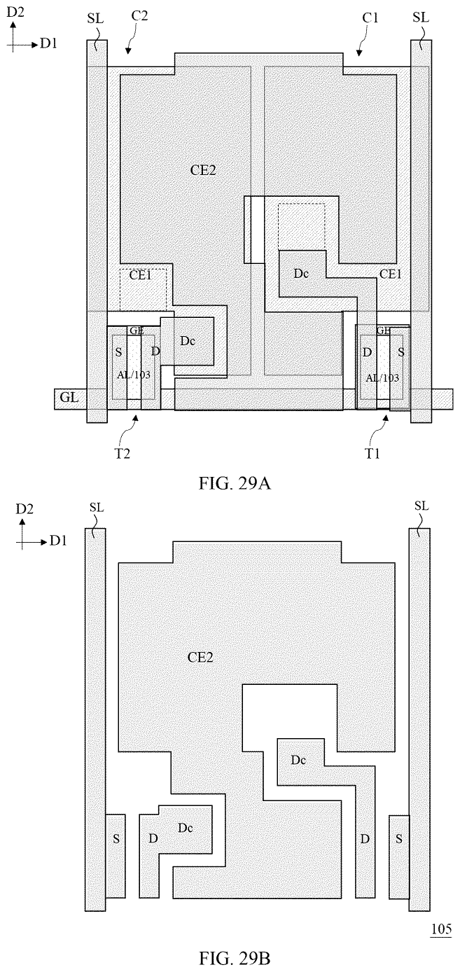

FIG. 29A illustrates a schematic layout of a stack of the conductive layer 101, the active layer 103 and a conductive layer 105. FIG. 29B illustrates a schematic layout of the conductive layer 105.

Referring to FIG. 29A and FIG. 29B, the conductive layer 105 includes source/drain electrodes S/D of the plurality of transistors T1 and T2, second electrode plates CE2 of the plurality of capacitors, and a plurality of data signal lines SL. The source electrodes S and the drain electrodes D of the transistors T1 and T2 cover parts of the corresponding active regions AL, respectively. The source electrode S is connected to the corresponding data signal line SL, and the drain electrode D may have a connection region Dc, which may have a larger size relative to other parts of the drain electrode D to facilitate subsequent connection with the pixel sub-electrode. The source/drain electrodes S/D of the transistors T1 and T2 may be spaced apart from the electrode plate CE2. In some embodiments, source/drain electrodes S/D of a plurality of transistors and second electrode plates CE2 of a plurality of capacitors disposed corresponding to the same pixel region may be disposed between adjacent data signal lines SL in the direction D1. The second electrode plate CE2 and the first electrode plate CE1 are disposed to face each other, that is, overlap with each other in the direction perpendicular to the main surface of the base substrate; and the second electrode plate CE2 exposes the connection region of the first electrode plate CE1. In other words, there is an opening in the conductive layer 105, and the opening overlaps with the first electrode plate CE1, so as to facilitate the subsequent electrical connection between the pixel sub-electrode and the first electrode plate. In some embodiments, the second electrode plates of a plurality of capacitors C1 and C2 disposed corresponding to the same pixel region may share the same one electrode plate CE2; in other words, the second electrode plates CE2 of the capacitors C1 and C2 are connected to each other.

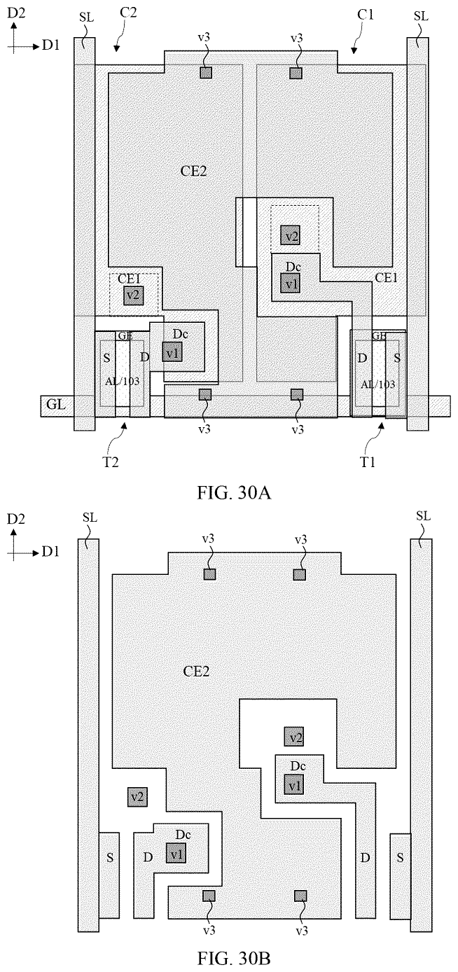

FIG. 30A illustrates a schematic layout of a stack of the conductive layer 101, the active layer 103, the conductive layer 105 and via holes in an insulating layer. FIG. 30B illustrates a schematic layout of a stack of the conductive layer 105 and via holes in an insulating layer.

Referring to FIGS. 30A and 30B, a plurality of via holes v1 respectively expose the drain electrodes D of a plurality of transistors T, for example, expose the connection regions Dc of the drain electrodes D. A plurality of via holes v2 respectively pass through the openings of the conductive layer 105 and expose the connection regions of a plurality of electrode plates CE1. A plurality of via holes v3 expose portions of the surface of the electrode plate CE2. In some examples, a plurality of via holes v3 are provided for the same electrode plate CE2, but the number of the via holes v3 is not limited to that illustrated in the figure.

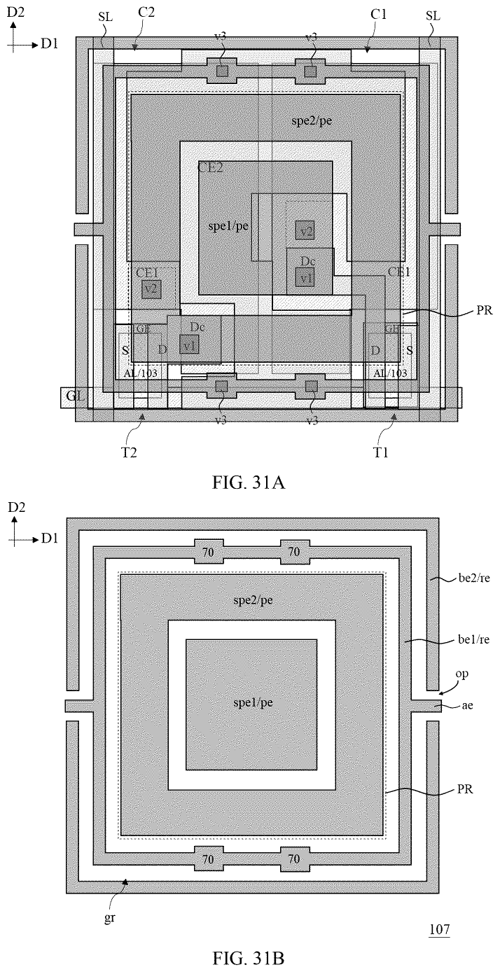

FIG. 31A illustrates a schematic layout of a stack of the conductive layer 101, the active layer 103, the conductive layer 105, via holes in the insulating layer and an electrode layer 107. FIG. 31B illustrates a schematic layout of the electrode layer 107.

Referring to FIGS. 31A and 31B, in some embodiments, the pixel electrode pe, the barrier wall electrode structure and the reflective electrode re may be disposed at the same layer of the electrode layer 107, and the barrier wall electrode structure may be multi-used as the reflective electrode re. That is, the barrier wall electrode structure and the reflective electrode share the same electrode structure.

In some embodiments, in each pixel region, the pixel electrode pe includes a pixel sub-electrode sp1 and a pixel sub-electrode sp2 spaced apart from each other. The pixel sub-electrode sp1 may have a block shape, such as a square, a rectangle or the like, or a suitable shape such as a circle or an ellipse. The pixel sub-electrode sp2 may be ring-shaped and surround the pixel sub-electrode sp1 in a direction parallel to the main surface of the base substrate. In this example, unlike the strip-shaped pixel sub-electrode used in the previous embodiment, the pixel electrode with such shape can realize different accumulation forms of charged particles located in the dispersant layer of the display device, thus realizing the diversification of display.

For example, the pixel sub-electrode sp1 is connected to the drain electrode D of the transistor T1 and the first electrode plate CE1 of the capacitor C1 through a via hole v1 and a via hole v3, respectively. The pixel sub-electrode sp1 can also be multi-used as the third electrode plate of the capacitor C1. The pixel sub-electrode sp2 is connected to the drain electrode D of the transistor T2 and the first electrode plate CE1 of the capacitor C2 through a via hole v1 and a via hole v3, respectively. The pixel sub-electrode sp2 can also be multi-used as the third electrode plate of the capacitor C2.

In some embodiments, the barrier wall electrode structure includes a barrier wall electrode be1, a barrier wall electrode be2 and a connection electrode ae. The barrier wall electrode be1 has a ring shape, such as a closed ring shape, so as to surround the pixel electrode pe in the corresponding pixel region PR. Each barrier wall electrode be1 is surrounded by a barrier wall electrode be2. The barrier wall electrode be2 has an opening op, the connection electrode ae is disposed at one side or opposite sides of the barrier wall electrode be1 in the direction D1; the connection electrode ae passes through the opening op of the barrier wall electrode be2 and is spaced apart from the barrier wall electrode be2, and is used for connecting adjacent barrier wall electrodes be1 and/or connecting a voltage signal (for example, Vcom signal). The layout of the barrier wall electrode structure is similar to the embodiment illustrated in FIGS. 24A and 24B, with the difference that the barrier wall electrode be1 in this embodiment has a relatively smaller size (e.g., width) and has a connection region 70 to be connected with the via, and the size of the connection region 70 may have a relatively larger size (e.g., width) relative to other parts of the barrier wall electrode be1. However, the present disclosure is not limited thereto. Here, the width of the barrier wall electrode refers to the width in a direction perpendicular to its extension direction.

The barrier wall electrode be1 is connected to the electrode plate CE2 located at the conductive layer 105 through the via hole v3. In some embodiments, the barrier wall electrode be1 and the electrode plate CE2 are configured to receive the Vcom signal, and the electrode plate CE2 may also be served as a signal shielding layer to shield the signal crosstalk to the pixel electrode sp caused by the signal line underlying thereof (for example, the signal line located at the conductive layer 101).

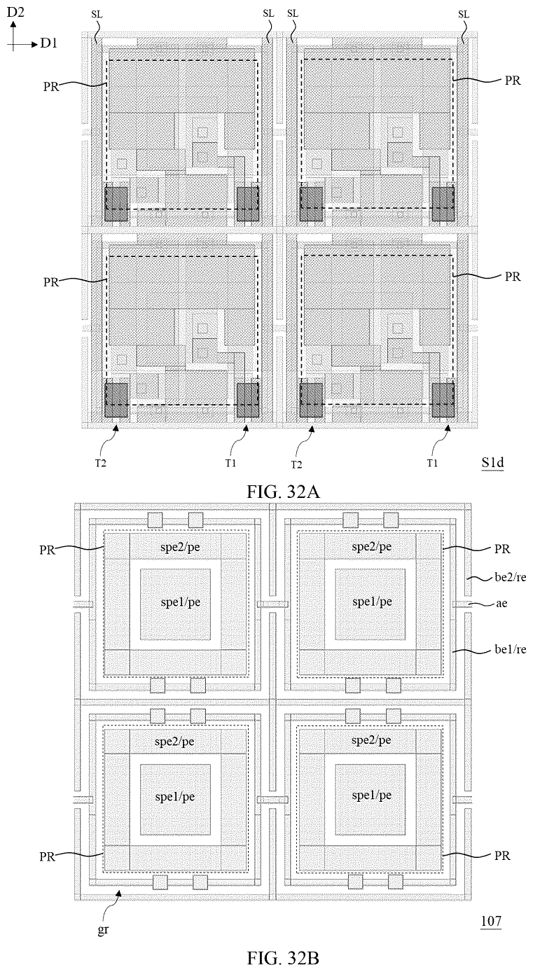

FIG. 32A illustrates a schematic plan layout of a stack of multiple layers in a plurality of pixel regions of a display region and in a barrier wall region surrounding the pixel regions, in an array substrate S1d. FIG. 32B illustrates a schematic plan layout of an electrode layer 107 in a plurality of pixel regions of a display region and in a barrier wall region surrounding the pixel regions, of the array substrate S1d.

Referring to FIGS. 32A and 32B, a plurality of pixel regions PR may be arranged in an array including a plurality of rows and a plurality of columns along directions D1 and D2. A plurality of transistors are also arranged in an array along directions D1 and D2, and a plurality of data signal lines SL extend in the direction D2 and are arranged in the direction D1, and each data signal line SL may be connected to the source electrodes S of a plurality of transistors T arranged in the same column in the direction D2. A plurality of barrier wall electrodes be1 are disposed in one-to-one correspondence with a plurality of pixel regions, and each barrier wall electrode be1 is located at the periphery of the corresponding pixel region PR, for example, at the side of the pixel sub-electrode spe2 away from the pixel sub-electrode spe1, and surrounds the pixel electrode located in the pixel region PR.

A plurality of barrier wall electrodes be1 may be correspondingly arranged in an array along the directions D1 and D2. For example, a plurality of barrier wall electrodes be1 located in the same row in the direction D1 may be electrically connected to each other through the connection electrode ae. Each barrier wall electrode be1 is surrounded by the barrier wall electrode be2. The barrier wall electrode be2 may be substantially in a grid shape and define a plurality of grid regions gr, and one pixel electrode and a barrier wall electrode be1 surrounding the one pixel electrode is provided in each grid region gr. In this embodiment, the layout of the barrier wall electrode structure in the electrode layer is similar to the embodiment illustrated in FIGS. 24A and 24B.

In some embodiments, the barrier wall electrodes be1 located in different rows may be configured to receive the same voltage signal (first voltage signal), for example, a Vcom signal; that is, all the barrier wall electrodes be1 may be configured to receive the same first voltage signal. The barrier wall electrode be2 is configured to receive a second voltage signal different from the first voltage signal. For example, the first voltage may be greater than or smaller than the second voltage. It should be understood that when the barrier wall electrode be2 has a notch and includes a plurality of portions disconnected from each other, the plurality of portions of the barrier wall electrode be2 may be configured to receive the same voltage signal.

Between every two pixel regions PR that are adjacent in the direction D1, the barrier wall electrode be2 and the barrier wall electrodes be1 located at two opposite sides of the barrier wall electrode be2 are configured to form two electric fields with opposite directions (for example, the leftward and rightward directions in the figure), thereby forming an electronic barrier wall between adjacent pixel regions in the direction D1. Between every two pixel regions PR that are adjacent in the direction D2, the barrier wall electrode be2 and the barrier wall electrodes be1 located at two opposite sides of the barrier wall electrode be2 are configured to form two electric fields with opposite directions (for example, the upward and downward directions in the figure), thereby forming an electronic barrier wall between adjacent pixel regions in the direction D2. In this embodiment, the way in which the barrier wall electrode be1 and the barrier wall electrode be2 form an electronic barrier wall is similar to that described in the previous embodiment with respect to FIGS. 18A and 18B, and will not be repeated here.

An embodiment of the present disclosure provides an electronic paper display device, which includes any one of the above-mentioned array substrates S1a-S1d. The electronic paper display device may be or include any of the electronic paper display devices illustrated in FIGS. 2A to 2D, for example, and the array substrate is used as the first substrate of the electronic paper display device. In the electronic paper display device including the array substrate of the embodiment of the present disclosure, a barrier wall electrode structure is disposed between any two adjacent pixel regions, and the electronic barrier wall generated by the barrier wall electrode structure between the adjacent pixel regions includes two opposite electric fields, so that the crosstalk caused by charged particles in the electronic paper display device between adjacent pixel regions can be effectively blocked, and the display quality of the display device can be further improved. On the other hand, the barrier wall electrode structure can be multi-used as a reflective electrode structure, thus improving the reflectivity under white state of the display device.

In the electronic paper display device including any one of array substrates S1a-S1d, a driving method for forming an electronic barrier wall includes: applying a first voltage signal to a barrier wall electrode be1 in a barrier wall electrode structure, and applying a second voltage signal different from the first voltage signal to a barrier wall electrode be2 in the barrier wall electrode structure, so as to form two opposite electric fields generated by corresponding portions of the barrier wall electrode be2 and the two barrier wall electrodes be1 between every two adjacent pixel regions, and the two opposite electric fields together constitute an electronic barrier wall between the adjacent pixel regions.

For example, the barrier wall electrode be1 may be connected to a signal line disposed at the same layer through the connection electrode ae, so that a first voltage signal can be applied to the barrier wall electrode be1 through the signal line and the connection electrode ae; alternatively, the barrier wall electrode be1 may be connected to a signal line in another layer through a via hole, so that the first voltage signal is applied to the barrier wall electrode be1 through the signal line; the barrier wall electrode be2 (for example, a portion thereof close to the edge of the display region) may be connected to a signal line disposed at the same layer, so that a second voltage signal can be applied to the barrier wall electrode be2 through the signal line; alternatively, the barrier wall electrode be2 may also be connected to a signal line located at another layer through a via hole, so that the second voltage signal can be applied to the barrier wall electrode be2 through the signal line. The present disclosure is not intended to limit the way in which the barrier wall electrodes be1 and be2 receive voltage signals. In some embodiments, one of the first voltage signal and the second voltage signal (for example, the first voltage signal) may be the same as the voltage signal received by the common electrode 201 in the second substrate of the electronic paper display device, for example, both are Vcom signals, but the present disclosure is not limited thereto. Through forming an electronic barrier wall between every two adjacent pixel regions, the crosstalk of charged particles between adjacent pixel regions can be effectively avoided, thus improving the display quality.

The following statements should be noted:

(1) The drawings of the present disclosure involve only the structure(s) in connection with the embodiment(s) of the present disclosure, and other structure(s) can be referred to common design(s).

(2) In case of no conflict, features in one embodiment or in different embodiments can be combined to obtain new embodiments.

What have been described above are only specific implementations of the present disclosure, the protection scope of the present disclosure is not limited thereto. Any modifications or substitutions easily occur to those skilled in the art within the technical scope of the present disclosure should be within the protection scope of the present disclosure. Therefore, the protection scope of the present disclosure should be based on the protection scope of the claims.

1. An array substrate, having a plurality of pixel regions arranged in an array and comprising:
a base substrate; and
a plurality of pixel electrodes and a barrier wall electrode structure, disposed on a side of the base substrate, wherein the plurality of pixel electrodes are respectively located in the plurality of pixel regions, and the barrier wall electrode structure is located between adjacent pixel regions, wherein
the plurality of pixel regions comprises a first pixel region and a second pixel region which are arranged in a first direction parallel to a main surface of the base substrate and are adjacent to each other, and the plurality of pixel electrodes comprise a first pixel electrode and a second pixel electrode respectively located in the first pixel region and the second pixel region; and
the barrier wall electrode structure comprises a first barrier wall electrode, a second barrier wall electrode and a third barrier wall electrode; at least a portion of the first barrier wall electrode, at least a portion of the second barrier wall electrode and at least a portion of the third barrier wall electrode are sequentially arranged between the first pixel region and the second pixel region in the first direction; the first barrier wall electrode and the second barrier wall electrode are configured to form a first electric field, the second barrier wall electrode and the third barrier wall electrode are configured to form a second electric field, the first electric field and the second electric field are in opposite directions and are configured to together constitute an electronic barrier wall; wherein the second barrier wall electrode is an electrode shared by the first electric field and the second electric field.

2. The array substrate according to claim 1, wherein at least a part of the first barrier wall electrode is located at a periphery of the first pixel region and surrounds the first pixel region in a direction parallel to the main surface of the base substrate; and
at least a part of the third barrier wall electrode is located at a periphery of the second pixel region and surrounds the second pixel region in the direction parallel to the main surface of the base substrate.

3. The array substrate according to claim 2, wherein the second barrier wall electrode surrounds the first barrier wall electrode and surrounds the third barrier wall electrode in the direction parallel to the main surface of the base substrate.

4. The array substrate according to claim 3, wherein the at least the portion of the second barrier wall electrode is located between the first barrier wall electrode and the third barrier wall electrode in the first direction, and has an opening, and
the first barrier wall electrode and the third barrier wall electrode are electrically connected to each other through a connection electrode passing through the opening.

5. The array substrate according to claim 1, wherein the plurality of pixel electrodes and the barrier wall electrode structure are disposed at a same layer and are spaced apart from each other; or
wherein the barrier wall electrode structure is disposed on a side of the plurality of pixel electrodes close to the base substrate, and an orthographic projection of the first barrier wall electrode on the base substrate covers the first pixel region and extends beyond an edge of an orthographic projection of the first pixel region on the base substrate; or an orthographic projection of the third barrier wall electrode on the base substrate covers the second pixel region and extends beyond an edge of an orthographic projection of the second pixel region on the base substrate.

6. (canceled)

7. The array substrate according to claim 1, wherein each pixel electrode comprises a plurality of pixel sub-electrodes, the plurality of pixel sub-electrodes are spaced apart from each other and configured to be connected to a plurality of data signal lines, respectively,
wherein each of one or more of the plurality of data signal lines comprises a data signal main line and a data signal auxiliary line connected to each other through a transfer electrode, and a plurality of data signal main lines is located in a region outside a corresponding pixel region.

8-9. (canceled)

10. The array substrate according to claim 7, wherein the plurality of pixel sub-electrodes comprise a plurality of strip electrodes arranged along the first direction and extending along a second direction, and the first direction and the second direction intersect with each other; or
wherein the plurality of pixel sub-electrodes comprise a first pixel sub-electrode and a second pixel sub-electrode, and the second pixel sub-electrode surrounds the first pixel sub-electrode in a direction parallel to the main surface of the base substrate.

11-12. (canceled)

13. The array substrate according to claim 1, further comprising a plurality of transistors and a plurality of capacitors, wherein each transistor comprises a gate electrode, a source electrode and a drain electrode, and each capacitor comprises at least a first electrode plate and a second electrode plate, and a pixel sub-electrode of each pixel electrode is electrically connected with one of the source electrode and the drain electrode of a corresponding transistor and is electrically connected with one of the first electrode plate and the second electrode plate of a corresponding capacitor, and the array substrate comprises:
a first conductive layer, a first insulating layer, a second conductive layer and a second insulating layer, which are sequentially disposed on a side of the base substrate, wherein the gate electrode and the first electrode plate are located at the first conductive layer, and the source electrode, the drain electrode and the second electrode plate are located at the second conductive layer; and
a first electrode layer, located on a side of the second insulating layer away from the base substrate,
wherein the plurality of pixel electrodes are disposed at the first electrode layer, the second insulating layer is provided with a first via hole, and the pixel sub-electrode is connected to the source electrode or the drain electrode of the corresponding transistor through the first via hole.

14. The array substrate according to claim 13, wherein
the second conductive layer is provided with an opening;
the second insulating layer and the first insulating layer are provided with a second via hole, and the second via hole passes through the opening of the second conductive layer and is spaced apart from the second conductive layer; and
the pixel sub-electrode is electrically connected to the first electrode plate of a capacitor through the second via hole.

15. The array substrate according to claim 14, wherein the capacitor further comprises a third electrode plate, and the pixel sub-electrode is multi-used as the third electrode plate of the capacitor, and the capacitor comprises double-layer capacitance formed between the second electrode plate and the first electrode plate, and between the second electrode plate and the third electrode plate.

16. (canceled)

17. The array substrate according to claim 13 any one of claims 13-16, wherein the barrier wall electrode structure is located at the first electrode layer, and the second insulating layer further comprises a third via hole, and the first barrier wall electrode and the third barrier wall electrode are respectively connected to the second electrode plates of corresponding capacitors through the third via hole; or
the array substrate further comprises:
a second electrode layer, located on a side of the first electrode layer close to the base substrate, and located between the first electrode layer and the second insulating layer; and
an organic layer, located between the first electrode layer and the second electrode layer,
wherein the barrier wall electrode structure is located at the second electrode layer and is multi-used as a reflective electrode.

18-23. (canceled)

24. The array substrate according to claim 13, wherein each pixel electrode comprises a first pixel sub-electrode, a second pixel sub-electrode and a third pixel sub-electrode which are arranged along the first direction;
in each pixel region, a plurality of transistors comprises a first transistor, a second transistor and a third transistor, which are respectively connected with the first pixel sub-electrode, the second pixel sub-electrode and the third pixel sub-electrode, respectively;
wherein the first transistor and the second transistor are arranged along the first direction, the third transistor is located on a side of the first transistor and the third transistor in a second direction, and at least a portion of an orthographic projection of the third transistor on a reference plane extending along the first direction is located between orthographic projections of the first transistor and the second transistor on the reference plane, and
the first direction intersects with the second direction.

25. The array substrate according to claim 24, wherein the plurality of pixel regions are arranged in a plurality of pixel rows along the first direction and arranged in a plurality of pixel columns along the second direction;
in a first pixel region and a third pixel region that are located in a same pixel column and in adjacent pixel rows, a plurality of transistors in the first pixel region are symmetrically disposed with a plurality of transistors in the third pixel region.

26. (canceled)

27. An electronic paper display device, comprising the array substrate according to claim 1, wherein the array substrate serves as a first substrate, and the electronic paper display device further comprises:
a second substrate, provided with a common electrode and disposed to face the first substrate; and
a dispersant layer, located between the first substrate and the second substrate, and comprising charged particles located in the plurality of pixel regions.

28. (canceled)

29. The electronic paper display device according to claim 27, wherein the charged particles comprise at least one of a first charged particle and a second charged particle, wherein the first charged particle has a first electrical property and the second charged particle has a second electrical property, and the first electrical property is opposite to the second electrical property.

30. The electronic paper display device according to claim 27, wherein there is free of physical barrier wall provided between adjacent pixel regions; or
the electronic paper display device further comprises a physical barrier wall disposed between the first substrate and the second substrate in a direction perpendicular to the main surface of the base substrate, and between adjacent pixel regions in a direction parallel to the main surface of the base substrate.

31-32. (canceled)

33. A driving method of an electronic paper display device according to claim 27, comprising:
applying a first voltage, a second voltage and a third voltage to the first barrier wall electrode, the second barrier wall electrode and the third barrier wall electrode, respectively,
wherein the first voltage is smaller than the second voltage, and the third voltage is smaller than the second voltage, so that an electronic barrier wall is formed by the barrier wall electrode structure and between the first pixel region and the second pixel region that are adjacent to each other and comprises two electric fields which have opposite directions and face away from each other; or
the first voltage is greater than the second voltage, and the third voltage is greater than the second voltage, so that an electronic barrier wall is formed by the barrier wall electrode structure and between the first pixel region and the second pixel region that are adjacent to each other and comprises two electric fields which have opposite directions and face towards each other.

34. The driving method of the electronic paper display device according to claim 33, wherein the first voltage is qual to the third voltage.

35. An array substrate, comprising a plurality of pixel regions arranged in an array, wherein the plurality of pixel regions are arranged in a plurality of pixel rows along a first direction and arranged in a plurality of pixel columns along a second direction, the first direction intersects with the second direction, and the array substrate comprises:
a base substrate; and
a plurality of pixel electrodes and a barrier wall electrode structure, disposed on a side of the base substrate, wherein the plurality of pixel electrodes are located in the plurality of pixel regions respectively, and the barrier wall electrode structure is located between adjacent pixel regions;
wherein the barrier wall electrode structure comprises a plurality of first barrier wall electrodes and a second barrier wall electrode, the plurality of first barrier wall electrodes are disposed in one-to-one correspondence with the plurality of pixel regions, at least a portion of each first barrier wall electrode surrounds one corresponding pixel region in a direction parallel to a main surface of the base substrate, and each first barrier wall electrode is surrounded by the second barrier wall electrode in the direction parallel to the main surface of the base substrate.

36. (canceled)

37. The array substrate according to claim 35, wherein the plurality of first barrier wall electrodes are arranged in a plurality of rows along the first direction; a portion of the second barrier wall electrode between every two adjacent first barrier wall electrodes located in a same row is provided with an opening; the barrier wall electrode structure further comprises a connection electrode, and the connection electrode passes through the opening, so that a plurality of first barrier wall electrodes located in a same row are electrically connected with each other through the connection electrode; or
wherein the second barrier wall electrode is in a grid shape and defines a plurality of grid regions; one pixel region and a first barrier wall electrode surrounding the one pixel region are provided in each grid region.

38-40. (canceled)
